(19) United States
(12) Patent Application Publication
(10) Pub. No.: US 2025/0393444 A1
(43) Pub. Date: Dec. 25, 2025

(54) DISPLAY DEVICE, WEARABLE ELECTRONIC DEVICE, AND METHOD OF MANUFACTURING DISPLAY DEVICE

(71) Applicant: Samsung Display Co., Ltd., Yongin-si (KR)

(72) Inventors: Yong Hoon KWON, Yongin-si (KR); Byung Hoon KIM, Yongin-si (KR); Sang Chul BYUN, Yongin-si (KR)

(21) Appl. No.: 19/097,753

(22) Filed: Apr. 1, 2025

(30) Foreign Application Priority Data
Jun. 21, 2024 (KR) 10-2024-0081269
Jul. 12, 2024 (KR) 10-2024-0092545

(51) Int. Cl. H10K 59/80; H10K 59/12; H10K 59/122; H10K 77/10

(52) U.S. Cl. CPC H10K 59/873; H10K 59/1201; H10K 59/122; H10K 77/10

(57) ABSTRACT

A display device includes a substrate in which a display area and a non-display area are defined and which has a first surface and a second surface opposite to each other in a thickness direction of the substrate and a side surface positioned between the first surface and the second surface, a display part on the first surface of the substrate in the display area and configured to display an image, a pad part on the first surface of the substrate in the non-display area, a filling layer on the display part and configured to cover the display part, and a chamfer portion positioned on at least a portion of the side surface of the substrate. The side surface of the substrate may include at least one crack extending in one direction intersecting the thickness direction.

### CROSS-REFERENCE TO RELATED APPLICATIONS

The present application claims priority to and the benefit of Korean Patent Application Number 10-2024-0081269, filed on Jun. 21, 2024, and Korean Patent Application Number 10-2024-0092545, filed on Jul. 12, 2024, in the Korean Intellectual Property Office, the entire content of each of which is incorporated herein by reference.

### BACKGROUND

### 1. Field

One or more embodiments of the present disclosure relate to a display device, a wearable electronic device, and a method of manufacturing the display device.

### 2. Description of the Related Art

Recently, with the rapid increase in interest in information displays, research and development on display devices have been continuously progressing.

### SUMMARY

One or more aspects of embodiments of the present disclosure are directed toward a display device with (having) improved manufacturing efficiency and reliability, a wearable electronic device, and a method of manufacturing the display device.

Additional aspects will be set forth in part in the description which follows and, in part, will be apparent from the description, or may be learned by practice of the presented embodiments.

According to one or more embodiments of the present disclosure, a display device includes a substrate in which a display area and a non-display area are defined and which has a first surface and a second surface opposite to each other in a thickness direction (e.g., in a thickness direction of the substrate) and a side surface positioned between the first surface and the second surface, a display part on (e.g., arranged on) the first surface of the substrate in the display area and configured to display an image, a pad part on (e.g., arranged on) the first surface of the substrate in the non-display area, a filling layer on (e.g., arranged) on the display part and configured to cover the display part, and a chamfer portion positioned on at least a portion of the side surface of the substrate. The side surface of the substrate may include at least one crack extending in a (e.g., one) direction intersecting the thickness direction.

The side surface of the substrate connected to the chamfer portion may have a curved surface.

The filling layer may include a transparent curable resin and may be positioned on an uppermost layer (e.g., uppermost layer of the display part) in the display area.

The substrate may include a silicon wafer substrate.

In one or more embodiments, the display device may further include a side sealing member on (e.g., arranged on) the chamfer portion to cover the chamfer portion.

The display part may include an anode on (e.g., arranged on) the substrate, a pixel defining layer on (e.g., arranged on) the substrate and including an opening configured to expose a portion of the anode, an emission structure on (e.g., arranged on) the anode and the pixel defining layer, and a cathode on (e.g., arranged on) the emission structure.

In one or more embodiments, the emission structure may include a first emission unit on (e.g., arranged on) the anode and the pixel defining layer and configured to emit light, an intermediate layer on (e.g., arranged on) the first emission unit, and a second emission unit on (e.g., arranged on) the intermediate layer and configured to emit light.

In one or more embodiments, the emission structure may include a first emission unit on (e.g., arranged on) the anode and the pixel defining layer and configured to emit light, a first intermediate layer on (e.g., arranged on) the first emission unit, a second emission unit on (e.g., arranged on) the first intermediate layer and configured to emit light, a second intermediate layer on (e.g., arranged on) the second emission unit, and a third emission unit on (e.g., arranged on) the second intermediate layer and configured to emit light.

According to one or more embodiments of the present disclosure, a wearable electronic device includes a display panel, and a lens on (e.g., arranged on) the display panel. The display panel may include a substrate in which a display area and a non-display area are defined and which has a first surface and a second surface opposite to each other in a thickness direction (e.g., a thickness direction of the substrate) and a side surface positioned between the first surface and the second surface, a display part on (e.g., arranged on) the first surface of the substrate in the display area and configured to display an image, a pad part on (e.g., arranged on) the first surface of the substrate in the non-display area, a filling layer on (e.g., arranged on) the display part and configured to cover the display part, and a chamfer portion positioned on at least a portion of the side surface of the substrate. The side surface of the substrate may include at least one crack extending in a (e.g., one) direction intersecting the thickness direction.

The filling layer may include a transparent curable resin and is positioned on an uppermost layer (e.g., uppermost layer of the display part) in the display area.

The substrate may include a silicon wafer substrate.

In one or more embodiments, the display panel may further include a side sealing member on (e.g., arranged on) the chamfer portion to cover the chamfer portion.

The display part may include an anode on (e.g., arranged on) the substrate, a pixel defining layer on (e.g., arranged on) the substrate and including an opening configured to expose a portion of the anode, an emission structure on (e.g., arranged on) the anode and the pixel defining layer, and a cathode on (e.g., arranged on) the emission structure.

The display device according to one or more embodiments described above may be manufactured through a method of manufacturing a display device, the method including preparing a mother substrate including a plurality of display cells, forming a filling layer on a display part of each of the display cells, irradiating a first laser beam onto a first surface of the mother substrate corresponding to a boundary point between two adjacent display cells among the display cells, and forming a cutting alignment mark on a second surface of the mother substrate opposite to the first surface, and turning over the mother substrate so that the second surface faces upward, irradiating a second laser beam onto the cutting alignment mark to form a chamfer portion, and then individually separating each of the display cells.

The first laser beam may be a laser having a wavelength that penetrates the mother substrate, and the second laser beam may be a laser having a wavelength that is absorbed by the mother substrate.

The substrate may include a silicon wafer substrate, the first laser beam may include an infrared laser, and the second laser beam may include a visible light laser.

In the forming of the cutting alignment mark, when the first laser beam is irradiated onto the first surface of the mother substrate, at least one crack may be formed inside the mother substrate.

In the individually separating of each of the display cells, when the second laser beam is irradiated onto the cutting alignment mark, heat may be generated, and the crack may propagate due to the heat so that the mother substrate may expand to be separated into each of the display cells individually.

In one or more embodiments, the method may further include, after the individually separating of each of the display cells, forming a side sealing member configured to cover the chamfer portion.

The filling layer may include a transparent curable resin and is positioned on an uppermost layer of the display part of each of the display cells.

### BRIEF DESCRIPTION OF THE DRAWINGS

Example embodiments will now be described more fully hereinafter with reference to the accompanying drawings; however, they may be embodied in different forms and should not be construed as limited to example embodiments set forth herein. Rather, these embodiments are provided so that this disclosure will be thorough and complete, and will fully convey the scope of the example embodiments to those skilled in the art. The above and other aspects, features, and advantages of certain embodiments of the present disclosure will be more apparent from the following description taken in conjunction with the accompanying drawings.

FIG. 1 is a schematic plan view illustrating a mother substrate according to one or more embodiments of the present disclosure.

FIG. 2 is a schematic enlarged view illustrating portion EA of FIG. 1.

FIG. 3 is a schematic cross-sectional view taken along the lines I-I′ of FIG. 2.

FIG. 4 is a schematic block diagram illustrating a display device according to one or more embodiments of the present disclosure.

FIG. 5 is a schematic plan view illustrating a display device according to one or more embodiments of the present disclosure.

FIG. 6 is an exploded perspective view illustrating a portion of the display panel of FIG. 5.

FIG. 7 is a schematic plan view illustrating one of pixels of FIG. 6 according to one or more embodiments of the present disclosure.

FIG. 8 is a schematic cross-sectional view taken along the line II-II′ of FIG. 7 according to one or more embodiments of the present disclosure.

FIG. 9 is a schematic cross-sectional view taken along the lines II-II′ of FIG. 7 according to one or more embodiments of the present disclosure.

FIG. 10 is a schematic cross-sectional view illustrating an emission structure included in one of first to third light-emitting elements of FIG. 8 or FIG. 9 according to one or more embodiments of the present disclosure.

FIG. 11 is a schematic cross-sectional view illustrating a portion of an emission structure included in one of the first to third light-emitting elements of FIG. 8 or FIG. 9 according to one or more embodiments of the present disclosure.

FIG. 12 is a schematic block diagram illustrating a method of manufacturing a display device according to one or more embodiments of the present disclosure.

FIGS. 13-21 are plan views and cross-sectional views illustrating process operations of a method of manufacturing a display device according to one or more embodiments of the present disclosure.

FIG. 22 is a schematic cross-sectional perspective view illustrating a portion of a second display cell of FIG. 21.

FIG. 23 shows schematic images showing cracks in FIG. 19.

FIG. 24 is a schematic block diagram illustrating a display system according to one or more embodiments of the present disclosure.

FIG. 25 is a schematic perspective view illustrating an application example of the display system of FIG. 24 according to one or more embodiments of the present disclosure.

FIG. 26 is a schematic view illustrating a state in which a user wears a head-mounted display device of FIG. 25 according to one or more embodiments of the present disclosure.

### DETAILED DESCRIPTION

It will be apparent to those skilled in the art that one or more suitable modifications and variations may be made in the present disclosure without departing from the spirit or scope of the disclosure, and specific example embodiments are illustrated in the drawings and explained in the detailed description. However, it should be understood that this is not intended to limit the disclosure to any specific disclosed form, and thus includes all modifications, equivalents, and substitutes included in the technical scope of the disclosure.

Hereinafter, example embodiments of the disclosure will be described in more detail with reference to the accompanying drawings. In the following description, it should be noted that only portions required for comprehension of operations according to the present disclosure will be described and descriptions of other portions will not be provided not to make subject matters of the disclosure obscure. In addition, the present disclosure is not limited to the following described embodiments but may also be embodied in other forms. Rather, these embodiments are provided so that the present disclosure will be thorough, and complete, and will fully convey the disclosure to those skilled in the art.

Throughout the present disclosure, it will be understood that if (e.g., when) an element is referred to as being “coupled” or “connected” to another element, it may be directly coupled or connected to the other element or one or more intervening elements may be present therebetween. Further, an expression that an element such as a layer, a region, a substrate, or a plate is placed “on” another element indicates not only embodiments in which the element is placed “directly on” the other element but also embodiments in which a further element may be interposed between the element and the other element. In contrast, if (e.g., when) an element is referred to as being “directly on” another element, there are no intervening element present therebetween. The terminology used herein is for the purpose of describing specific embodiments and is not intended to limit the disclosure. Throughout the disclosure, unless explicitly described to the contrary, the word “comprise/include/has” and variations such as “comprises/includes/have” or “comprising/including/having” will be understood to imply the inclusion of stated elements but not the exclusion of any other elements. “At least any one of X, Y, and Z,” “at least any one of X, Y, or Z,” “at least any one selected from among X, Y, and Z,” and “at least any one selected from the group consisting of X, Y, and Z” may be construed as each of X, Y, and Z or a (e.g., any suitable) combination of two or more of X, Y, and Z (for example, XYZ, XYY, YZ, and ZZ). As used herein, “and/or” “or” may include one or more combinations of corresponding components.

It will be understood that, although the terms “first,” “second,” “third,” and so on may be used herein to describe one or more suitable elements, these elements are not limited by these terms. These terms are used to distinguish one element from another element. Thus, a first element described could also be termed as a second or third element without departing from the spirit and scope of the disclosure. As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure.

Spatially relative terms, such as “beneath,” “below,” “lower,” “above,” “upper,” and/or the like, may be used herein for descriptive purposes, and, thereby, to describe one element or feature's relationship to another element(s) or feature(s) as shown in the drawings. Spatially relative terms are intended to encompass different orientations of a device in use, operation, and/or manufacture in addition to the orientation depicted in the drawings. For example, if (e.g., when) the device in the drawings is turned over (e.g., turned upside down), elements described as “below” or “beneath” other elements or features would then be oriented “above” the other elements or features. Thus, in one or more embodiments, the example term “below” may encompass both (e.g., simultaneously) an orientation of above and below directions. Furthermore, the device may be otherwise oriented (e.g., rotated 90 degrees or at other orientations), and, as such, the spatially relative descriptors used herein interpreted accordingly.

One or more embodiments are described with reference to drawings that schematically illustrate example embodiments. Accordingly, it will be expected that the shapes may vary depending, for example, on tolerances and/or manufacturing techniques. Accordingly, one or more embodiments disclosed herein should not be construed as limited to the specific shapes shown herein, but should be construed to include deviations in shapes that result from, for instance, manufacturing. As such, the shapes shown in the drawings may not depict the certain practical shapes of regions of the device, and the present embodiments are not limited thereto.

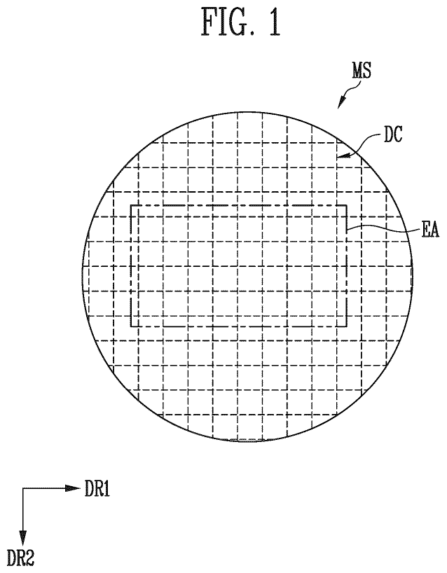

FIG. 1 is a schematic plan view illustrating a mother substrate MS according to one or more embodiments of the present disclosure.

Referring to FIG. 1, the mother substrate MS may be a substrate for concurrently (e.g., simultaneously) manufacturing a plurality of display cells DC for process convenience. In other words, the mother substrate MS may be the substrate on which a plurality of display cells DC are manufactured for process convenience. The mother substrate MS may include one or more unit areas. The unit area may be a portion corresponding to an individual display cell DC (or an individual display device), and the individual display cell DC may be formed for each unit area.

In one or more embodiments, the mother substrate MS may be a silicon wafer substrate formed using a semiconductor process. In one or more embodiments, the mother substrate MS may include a semiconductor material such as a Group IV semiconductor, a Group III-V compound semiconductor, or a Group II-VI compound semiconductor, but embodiments of the present disclosure are not limited thereto.

Each of the display cells DC may be individually separated to serve as a display device, and a plurality of display cells DC may be formed concurrently (e.g., simultaneously) on the mother substrate MS and then separated through a cutting process and/or the like. In one or more embodiments, as shown in a portion EA of FIG. 1, the plurality of display cells DC may be provided on the mother substrate MS and arranged in a matrix form according to a row (or a display cell row) extending in a first direction DR1 and a column (or a display cell column) extending in a second direction DR2, but embodiments of the present disclosure are not limited thereto.

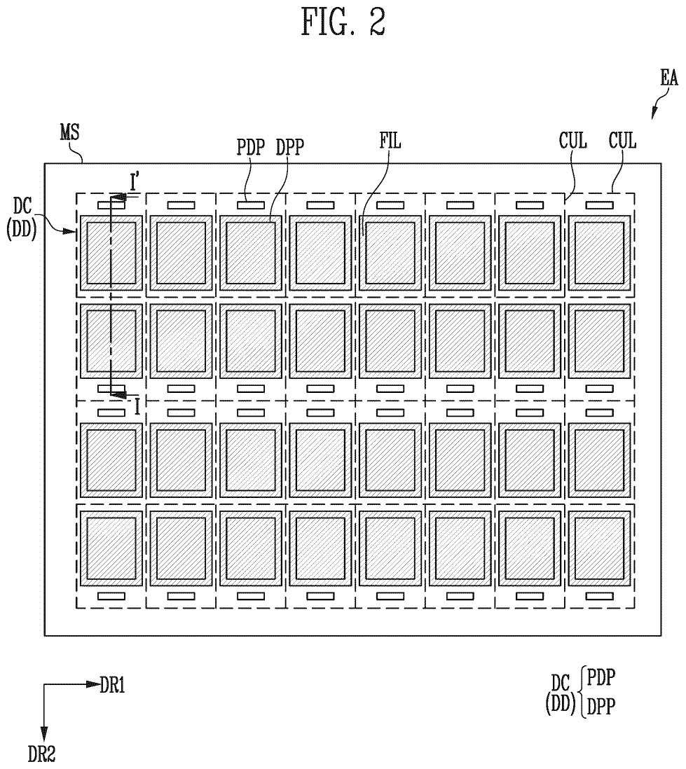

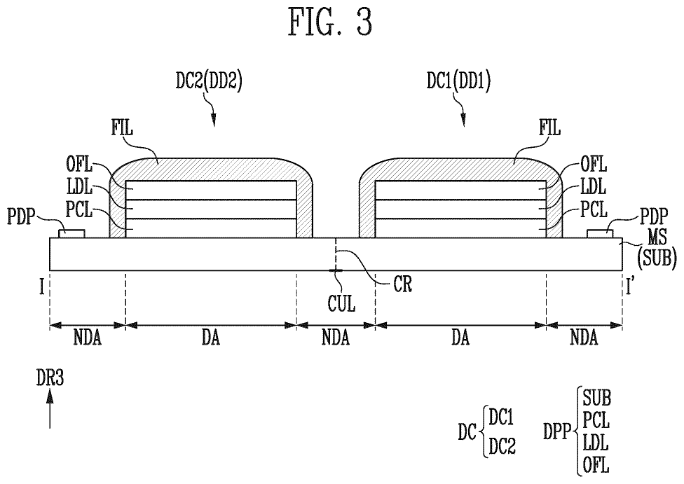

FIG. 2 is a schematic enlarged view illustrating portion EA of FIG. 1. FIG. 3 is a schematic cross-sectional view taken along the lines I-I′ of FIG. 2.

Referring to FIGS. 1 to 3, the mother substrate MS may be provided with a cutting line CUL corresponding to each of the display cells DC (or display devices DD). Each of the display cells DC (or the display devices DD) may be individually separated through a process of cutting the mother substrate MS along the cutting line CUL using a laser beam. In one or more embodiments of the present disclosure, the term “display cell” may be interchangeable with the term “display device.”

Each of the display cells DC may be a flat display device, a flexible display device, a curved display device, a foldable display device, a bendable display device, or a rollable display device. In one or more embodiments, each of the display cells DC may be applied to a transparent display device, a head-mounted display (HMD) device, a wearable display device, and/or the like.

The mother substrate MS may become a substrate SUB which is a base substrate for the display cells DC after the display cells DC are individually separated.

The display cells DC may include first display cells DC1 (or first display devices DD1) and second display cells DC2 (or second display devices DD2). The first display cells DC1 may be arranged in odd-numbered rows of the mother substrate MS, and the second display cells DC2 may be arranged in even-numbered rows of the mother substrate MS. In one or more embodiments, the first display cells DC1 and the second display cells DC2 may be provided to be substantially the same. Hereinafter, the first display cells DC1 and the second display cells DC2 are collectively referred to as display cell DC and/or display cells DC.

Each of the display cells DC may include a display part DPP and a pad part PDP. The display part DPP may be positioned in a display area DA, and the pad part PDP may be positioned in one area of a non-display area NDA, for example, a pad area.

The display part DPP may include the substrate SUB, a pixel circuit layer PCL, a light-emitting element layer LDL, and an optical functional layer OFL.

The substrate SUB may be one area of the mother substrate MS and may be a silicon wafer substrate. The substrate SUB may include the display area DA in which an image is displayed and the non-display area NDA in which an image is not displayed.

The pixel circuit layer PCL may be on (e.g., arranged on) the substrate SUB and may include circuit elements.

The light-emitting element layer LDL may be on (e.g., arranged on) the pixel circuit layer PCL and may include light-emitting elements.

The optical functional layer OFL may be on (e.g., arranged on) the light-emitting element layer LDL and may include a microlens array to improve the extraction efficiency of light emitted from the light-emitting element layer LDL, but embodiments of the present disclosure are not limited thereto.

After a process of separating the mother substrate MS into units of the display cells DC, an external connection terminal may be coupled to the pad part PDP. The display cell DC may be electrically connected to the outside through the external connection terminal coupled to the pad part PDP.

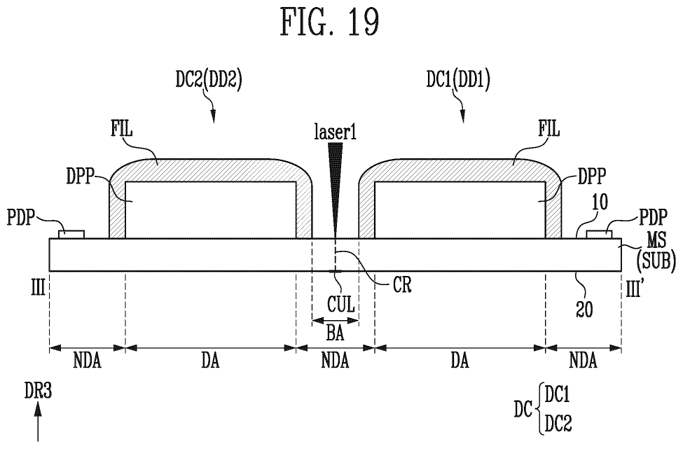

The display part DPP may be positioned adjacent to cutting alignment marks CUL (corresponding to the cutting line CUL) positioned between the first display cells DC1 and the second display cells DC2. In this regard, if (e.g., when) viewed from above (e.g., in a plan view), the display part DPP of each of the first display cells DC1 and the display part DPP of each of the second display cells DC2 may face (e.g., may be adjacent to) each other in the second direction DR2, but the arrangement of the display part DPP of each of the first and second display cells DC1 and DC2 is not limited thereto. The cutting alignment mark CUL may be formed on a rear surface of the mother substrate MS and may correspond to a cutting line to which a laser beam is irradiated in a process of separating the mother substrate MS into a unit of each display cell DC. The cutting alignment mark CUL may be formed in substantially the same process as cracks CR formed in an internal space of the mother substrate MS. The cutting alignment mark CUL and the crack CR will be described in more detail with reference to FIG. 19.

Each of the display cells DC may include a filling layer FIL that is positioned on the display portion DPP and covers the display portion DPP.

The filling layer FIL may include a curable resin having a viscosity of a certain level or more. In one or more embodiments, the filling layer FIL may be made of an epoxy-based resin or a silicon-based resin. For example, in one or more embodiments, the epoxy-based resin may have a viscosity (cps) of about 19 to about 5,400, but embodiments of the disclosure are not limited thereto.

In one or more embodiments, after the display part DPP is formed on the mother substrate MS, a coating solution corresponding to a base material of the filling layer FIL may be applied on the display part DPP, and then a curing process using light or heat may be performed to form the filling layer FIL in each of the display cells DC. However, a method of forming the filling layer FIL is not limited to the above-described embodiments.

The filling layer FIL may be positioned on an uppermost layer of the display part DPP in the display area DA of each display cell DC. For example, the filling layer FIL may be positioned on the uppermost layer of the display part DPP in the display area DA of each display cell DC and may entirely cover components positioned below the filling layer FIL. In one or more embodiments, the filling layer FIL may protect each display cell DC from an external impact and/or the like and may provide an input surface and/or a display surface to a user. The filling layer FIL may be a cover member.

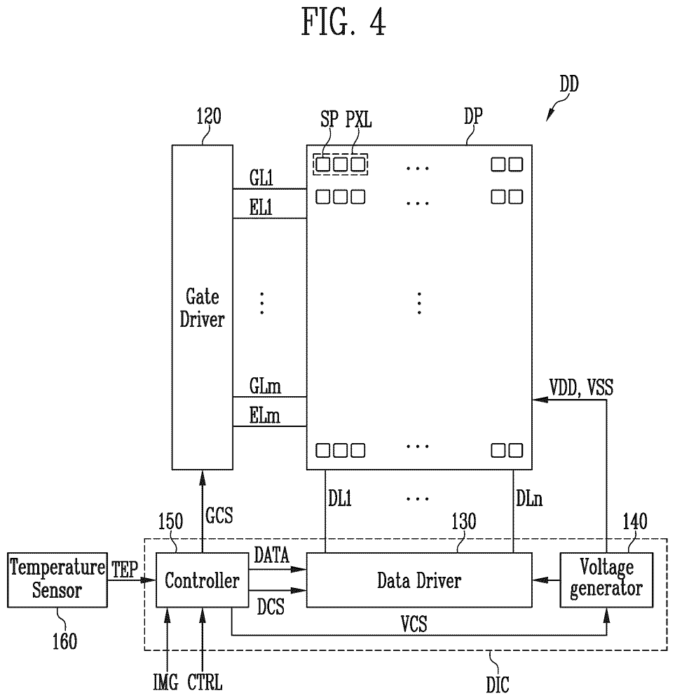

FIG. 4 is a schematic block diagram illustrating a display device DD according to one or more embodiments of the present disclosure.

Referring to FIG. 4, the display device DD may include a display panel DP, a gate driver 120, a data driver 130, a voltage generator 140, and a controller 150. The display panel DP may include a display part DPP and a filling layer FIL described with reference to FIGS. 2 and 3.

The display panel DP may include subpixels SP. The subpixels SP may be connected to the gate driver 120 through first to m^{th} gate lines GL1 to GLm. The subpixels SP may be connected to the data driver 130 through first to n^{th} data lines DL1 to DLn.

Each of the subpixels SP may include one or more light-emitting elements configured to generate light. Accordingly, each of the subpixels SP may generate light with a specific color such as red, green, blue, cyan, magenta, or yellow. Two or more subpixels among the subpixels SP may constitute one pixel PXL. For example, in one or more embodiments, as shown in FIG. 4, three subpixels may constitute one pixel PXL.

The gate driver 120 may be connected to the subpixels SP arranged in a row direction through the first to m^{th} gate lines GL1 to GLm. The gate driver 120 may output gate signals to the first to m^{th} gate lines GL1 to GLm in response to a gate control signal GCS. In one or more embodiments, the gate control signal GCS may include a start signal indicating the start of each frame, a horizontal synchronization signal for outputting gate signals in synchronization with a timing at which data signals are applied, and/or the like.

In one or more embodiments, first to m^{th} emission control lines EL1 to ELm connected to the subpixels SP in the row direction may be further provided. In this regard, the gate driver 120 may include an emission control driver configured to control the first to m^{th} emission control lines EL1 to ELm. The emission control driver may operate under the control of the controller 150.

In one or more embodiments, the gate driver 120 may be arranged at one side of the display panel DP. However, embodiments of the present disclosure are not limited thereto. For example, in one or more embodiments, the gate driver 120 may be divided into two or more physically and/or logically separated drivers, and such drivers may be arranged at one side of the display panel DP and the other side of the display panel DP opposite the one side. As such, the gate driver 120 may be arranged around the display panel DP in one or more suitable shapes according to one or more embodiments.

The data driver 130 may be connected to the subpixels SP arranged in a column direction through the first to n^{th} data lines DL1 to DLn. The data driver 130 may receive image data DATA and a data control signal DCS from the controller 150. The data driver 130 may operate in response to the data control signal DCS. In one or more embodiments, the data control signal DCS may include a source start pulse, a source shift clock, a source output enable signal, and/or the like.

The data driver 130 may apply data signals having grayscale voltages corresponding to the image data DATA to the first to n^{th} data lines DL1 to DLn using voltages from the voltage generator 140. In the case that a gate signal is applied to each of the first to m^{th} gate lines GL1 to GLm, data signals corresponding to the image data DATA may be applied to the data lines DL1 to DLn. Accordingly, the corresponding subpixels SP may generate light corresponding to the data signals. Accordingly, an image may be displayed on the display panel DP.

In one or more embodiments, the gate driver 120 and the data driver 130 may each include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device DD. For example, the voltage generator 140 may be configured to receive an input voltage from outside of the display device DD, adjust the received voltage, and regulate the adjusted voltage to generate a plurality of voltages.

In one or more embodiments, the voltage generator 140 may generate a first power voltage VDD and a second power voltage VSS and may provide the generated first and second power voltages VDD and VSS to the subpixels SP. The first power voltage VDD may have a relatively high voltage level, and the second power voltage VSS may have a lower voltage level than the first power voltage VDD. In one or more embodiments, the first power voltage VDD or the second power voltage VSS may be provided by an external device of the display device DD.

In addition, the voltage generator 140 may generate one or more suitable and/or designed voltages. For example, in one or more embodiments, the voltage generator 140 may generate an initialization voltage applied to the subpixels SP. For example, in one or more embodiments, during a sensing operation of sensing electrical characteristics of transistors and/or the light-emitting elements of the subpixels SP, a certain reference voltage may be applied to the first to n^{th} data lines DL1 to DLn, and the voltage generator 140 may generate such a reference voltage.

The controller 150 may control the overall operation of the display device DD. The controller 150 may receive input image data IMG and a control signal CTRL for controlling the display of the input image data IMG from the outside. The controller 150 may provide the gate control signal GCS, the data control signal DCS, and the voltage control signal VCS in response to the received control signal CTRL.

The controller 150 may output image data DATA by converting the input image data IMG to be suitable for the display device DD or display panel DP. In one or more embodiments, the controller 150 may output the image data DATA by aligning the input image data IMG to be suitable for the subpixels SP in a row unit.

Two or more components of (e.g., selected from among) the data driver 130, the voltage generator 140, and the controller 150 may be mounted on one integrated circuit. As shown in FIG. 4, in one or more embodiments, the data driver 130, the voltage generator 140, and the controller 150 may be included in a driver integrated circuit DIC. In these embodiments, the data driver 130, the voltage generator 140, and the controller 150 may be components functionally separated in one driver integrated circuit DIC. In one or more embodiments, at least one of the data driver 130, the voltage generator 140, or the controller 150 may be provided as a component separated as a driver integrated circuit DIC.

The display device DD may include one or more temperature sensors 160. The temperature sensor 160 may be configured to detect a temperature therearound and generate temperature data TEP indicating the detected temperature. In one or more embodiments, the temperature sensor 160 may be arranged adjacent to the display panel DP and/or the driver integrated circuit DIC.

The controller 150 may control one or more suitable operations of the display device DD in response to the temperature data TEP. In one or more embodiments, the controller 150 may adjust the luminance of an image output from the display panel DP in response to the temperature data TEP. For example, the controller 150 may adjust data signals and the first and second power voltages VDD and VSS by controlling components such as the data driver 130 and/or the voltage generator 140.

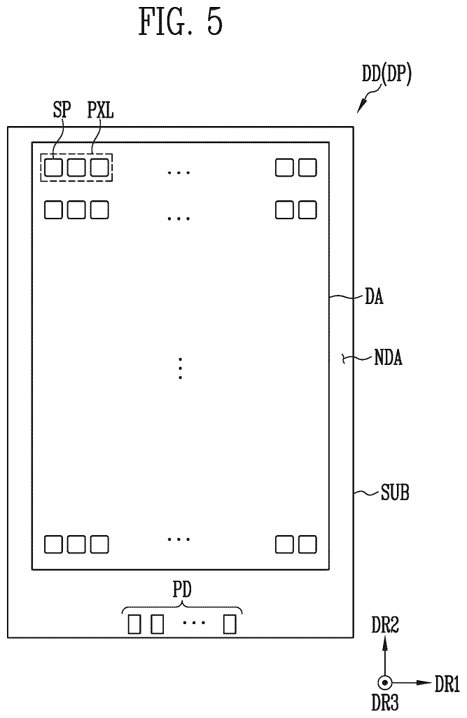

FIG. 5 is a schematic plan view illustrating a display device DD according to one or more embodiments of the present disclosure. In FIG. 5, for convenience, a structure of the display device DD, for example, a structure of a display panel DP provided in the display device DD, is briefly shown centered on a display area DA in which an image is displayed.

Referring to FIG. 5, the display panel DP may include a display area DA and a non-display area NDA.

The display panel DP may display an image through the display area DA. The non-display area NDA may be arranged around the display area DA.

The display panel DP may include a substrate SUB, subpixels SP, and pads PD.

In embodiments in which the display panel DP is used as a display screen of a head mounted display (HMD), a virtual reality (VR) device, a mixed reality (MR) device, an augmented reality (AR) device, and/or the like, the display panel DP may be positioned very close to eyes of a user. In these embodiments, the subpixels SP with a relatively high degree of integration may be desired or required. In order to increase a degree of integration of the subpixels SP, the substrate SUB may be provided as a silicon substrate (or a silicon wafer), but embodiments of the present disclosure are not limited thereto. The subpixels SP and/or the display panel DP may be formed on the silicon substrate SUB. The display device DD including the display panel DP formed on the substrate SUB, which is a silicon substrate, may be referred to as an OLED on silicon (OLEDoS) display device.

The subpixels SP may be arranged in the display area DA on the substrate SUB. The subpixels SP may be arranged in a matrix form in a first direction DR1 and a second direction DR2 intersecting the first direction DR1, but the arrangement form of the subpixels SP is not limited thereto. For example, in one or more embodiments, the subpixels SP may be arranged in a zigzag form in the first direction DR1 and the second direction DR2. For example, in one or more embodiments, the subpixels SP may be arranged in a PENTILE® form (for example, an RGBG matrix, an RGBG structure, or an RGBG matrix structure). PENTILER is a duly registered trademark of Samsung Display Co., Ltd. The first direction DR1 may be a row direction, and the second direction DR2 may be a column direction.

Among the plurality of subpixels SP, two or more subpixels SP may constitute one pixel PXL.

Components for controlling the subpixels SP may be arranged in the non-display area NDA on the substrate SUB. For example, in one or more embodiments, interconnects connected to the subpixels SP, such as the first to m^{th} gate lines GL1 to GLm and the first to n^{th} data lines DL1 to DLn of FIG. 4, may be arranged in the non-display area NDA.

In one or more embodiments, at least one of the gate driver 120, the data driver 130, the voltage generator 140, the controller 150, or the temperature sensor 160 of FIG. 4 may be integrated in the non-display area NDA of the display panel DP. In one or more embodiments, the gate driver 120 of FIG. 4 may be mounted on the display panel DP and arranged in the non-display area NDA. In one or more embodiments, the gate driver 120 may be implemented as an integrated circuit separate from the display panel DP. In one or more embodiments, the temperature sensor 160 may be arranged in the non-display area NDA to detect a temperature of the display panel DP.

The pads PD may be arranged in the non-display area NDA on the substrate SUB. The pads PD may be electrically connected to the subpixels SP through interconnects. For example, in one or more embodiments, the pads PD may be connected to the subpixels SP through the first to n^{th} data lines DL1 to DLn. The pads PD may be included in the pad part PDP described with reference to FIGS. 2 and 3.

The pads PD may allow the display panel DP to interface with other components of the display device DD. In one or more embodiments, voltages and signals necessary for operating components included in the display panel DP may be provided from the driver integrated circuit DIC of FIG. 4 through the pads PD. For example, in one or more embodiments, the first to n^{th} data lines DL1 to DLn may be connected to the driver integrated circuit DIC through the pads PD. For example, in one or more embodiments, first and second power voltages VDD and VSS may be received from the driver integrated circuit DIC through the pads PD. For example, in the case that the gate driver 120 is mounted on the display panel DP, a gate control signal GCS may be transmitted from the driver integrated circuit DIC to the gate driver 120 through the pads PD.

In one or more embodiments, a circuit board may be electrically connected to the pads PD using a conductive adhesive member such as an anisotropic conductive film. In these embodiments, the circuit board may be a flexible printed circuit board (FPCB) or a flexible film which is made of a flexible material. The driver integrated circuit DIC may be mounted on the circuit board and electrically connected to the pads PD.

In one or more embodiments, the display area DA may have one or more suitable shapes. The display area DA may have a closed loop shape including straight and/or curved sides. For example, in one or more embodiments, the display area DA may have a shape such as a polygonal shape, a circular shape, a semicircular shape, and/or an elliptical shape.

In one or more embodiments, the display panel DP may have a flat display surface. In one or more embodiments, the display panel DP may have a display surface that is at least partially round. In one or more embodiments, the display panel DP may be bendable, foldable, or rollable. In these embodiments, the display panel DP and/or the substrate SUB may include materials with flexible properties.

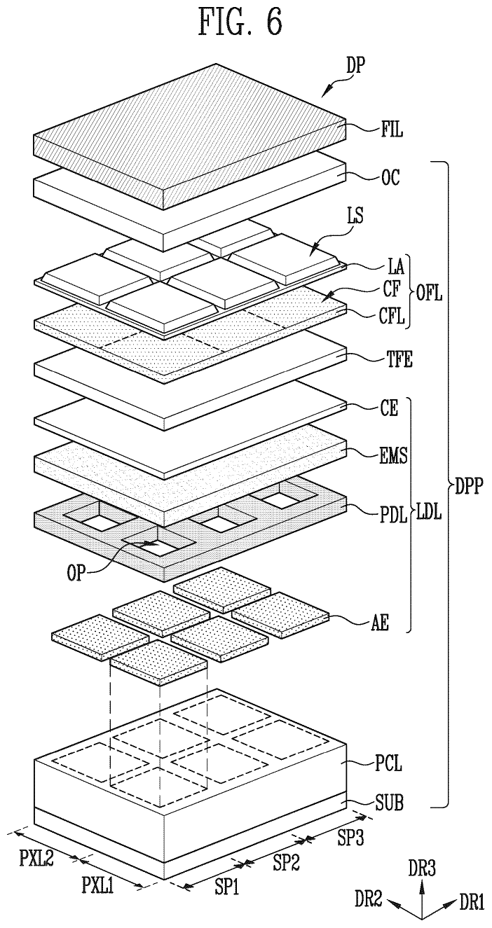

FIG. 6 is an exploded perspective view illustrating a portion of the display panel DP of FIG. 5. In FIG. 6, for clear and concise description, portions of the display panel DP corresponding to two pixels PXL1 and PXL2 among the pixels PXL of FIG. 5 are schematically shown. Portions of the display panel DP corresponding to the remaining pixels may be provided similarly.

Referring to FIGS. 5 and 6, in one or more embodiments, each of first and second pixels PXL1 and PXL2 may include first to third subpixels SP1 to SP3. However, embodiments of the present disclosure are not limited thereto. For example, in one or more embodiments, each of the first and second pixels PXL1 and PXL2 may include four subpixels or two subpixels.

In FIG. 6, the first to third subpixels SP1 to SP3 are shown as having quadrangular shapes if (e.g., when) viewed in a third direction DR3 that intersects the first and second directions DR1 and DR2 and are shown as having the same size. However, embodiments of the present disclosure are not limited thereto. According to one or more embodiments, the first subpixel SP1, the second subpixel SP2, and the third subpixel SP3 may be modified to have one or more suitable shapes.

The display panel DP may include a display part DPP and a filling layer FIL. The display part DPP may include a substrate SUB, a pixel circuit layer PCL, a light-emitting element layer LDL, an encapsulation layer TFE, an optical functional layer OFL, and an overcoat layer OC.

In one or more embodiments, the substrate SUB may include a silicon wafer substrate formed using a semiconductor process. The substrate SUB may include a semiconductor material suitable for forming circuit elements. For example, in one or more embodiments, the semiconductor material may include silicon, germanium, and/or silicon-germanium. The substrate SUB may be provided from a bulk wafer, an epitaxial layer, a silicon-on-insulator (SOI) layer, or a semiconductor-on-insulator (SeOI) layer. In one or more embodiments, the substrate SUB may include a glass substrate. In one or more embodiments, the substrate SUB may include a polyimide (PI) substrate.

The pixel circuit layer PCL may be on (e.g., arranged on) the substrate SUB. The substrate SUB and/or the pixel circuit layer PCL may include insulating layers and conductive patterns arranged between the insulating layers. The conductive patterns of the pixel circuit layer PCL may function as at least some of circuit elements, interconnects, and/or the like. In one or more embodiments, the conductive patterns may include copper, but embodiments of the present disclosure are not limited thereto.

The circuit elements may include a subpixel circuit for each of the first to third subpixels SP1 to SP3. The subpixel circuit may include transistors and one or more capacitors. Each transistor may include a semiconductor portion including a source region, a drain region, and a channel region, and a gate electrode overlapping the semiconductor portion. In one or more embodiments, the substrate SUB may be provided as a silicon substrate, the semiconductor portion may be included in the substrate SUB, and the gate electrode may be included in the pixel circuit layer PCL as a conductive pattern of the pixel circuit layer PCL. In one or more embodiments, the substrate SUB may be provided as a glass substrate or a PI substrate, the semiconductor portion and the gate electrode may be included in the pixel circuit layer PCL. Each capacitor may include electrodes spaced and/or apart (e.g., spaced apart or separated) from each other. For example, in one or more embodiments, each capacitor may include electrodes spaced and/or apart (e.g., spaced apart or separated) from each other on a plane defined by the first and second directions DR1 and DR2. For example, in one or more embodiments, each capacitor may include electrodes spaced and/or apart (e.g., spaced apart or separated) from each other in the third direction DR3 with an insulating layer interposed therebetween.

Interconnects of the pixel circuit layer PCL may include signal lines connected to each of the first to third subpixels SP1 to SP3, for example, a gate line, an emission control line, and a data line.

The light-emitting element layer LDL may include an anode AE, a pixel defining layer PDL, an emission structure EMS, and a cathode CE.

The anode AE may be on (e.g., arranged on) the pixel circuit layer PCL. The anode AE may be in contact with the circuit elements of the pixel circuit layer PCL. The anode AE may include an opaque conductive material capable of reflecting light, but embodiments of the present disclosure are not limited thereto.

The pixel defining layer PDL may be on (e.g., arranged on) the anode AE. The pixel defining layer PDL may include an opening OP exposing a portion of each anode AE. The openings OP of the pixel defining layer PDL may be understood as emission areas respectively corresponding to the first to third subpixels SP1 to SP3.

In one or more embodiments, the pixel defining layer PDL may include an inorganic material. In these embodiments, the pixel defining layer PDL may include a plurality of stacked inorganic layers. For example, in one or more embodiments, the pixel defining layer PDL may include silicon oxide (SiOₓ) and/or silicon nitride (SiNₓ). In one or more embodiments, the pixel defining layer PDL may include an organic material. However, the material of the pixel defining layer PDL is not limited thereto.

The emission structure EMS may be on (e.g., arranged on) the anode AE exposed by the opening OP of the pixel defining layer PDL. The emission structure EMS may include an emission layer configured to generate light, an electron transport layer configured to transport electrons, and a hole transport layer configured to transport holes.

In one or more embodiments, the emission structure EMS may fill the opening OP of the pixel defining layer PDL and may be entirely arranged on the pixel defining layer PDL. For example, in one or more embodiments, the emission structure EMS may extend over the first to third subpixels SP1 to SP3. In these embodiments, at least some of the layers in the emission structure EMS may be disconnected or bent at boundaries between the first to third subpixels SP1 to SP3. However, embodiments of the present disclosure are not limited thereto. For example, in one or more embodiments, portions of the emission structure EMS corresponding to the first to third subpixels SP1 to SP3 may be separated from each other, and each of the portions may be arranged in the opening OP of the pixel defining layer PDL.

The cathode CE may be on (e.g., arranged on) the emission structure EMS. The cathode CE may extend over the first to third subpixels SP1 to SP3. In this way, the cathode CE may serve as a common electrode for the first to third subpixels SP1 to SP3.

In one or more embodiments, the cathode CE may be a thin metal layer having a thin thickness to transmit light emitted from the emission structure EMS. The cathode CE may be made of a metal material or a transparent conductive material to have a relatively thin thickness. In one or more embodiments, the cathode CE may include at least one selected from among one or more suitable transparent conductive materials such as indium tin oxide, indium zinc oxide, indium tin zinc oxide, aluminum zinc oxide, gallium zinc oxide, zinc tin oxide, and gallium tin oxide. In one or more embodiments, the cathode CE may include at least one selected from among silver (Ag), magnesium (Mg), and a (e.g., any suitable) mixture thereof. However, the material of the cathode CE is not limited thereto.

One anode AE of (e.g., selected from among) the anodes AE, a portion of the emission structure EMS overlapping the one anode AE, and a portion of the cathode CE overlapping the portion of the emission structure EMS overlapping the one anode AE may be understood as constituting one light-emitting element. For example, each of light-emitting elements of the first to third subpixels SP1 to SP3 may include one anode AE, a portion of the emission structure EMS overlapping the one anode AE, and the cathode CE overlapping the portion of the emission structure EMS overlapping the one anode AE. In each of the first to third subpixels SP1 to SP3, holes injected from the anode AE and electrons injected from the cathode CE may be transported into respective emission layer of the emission structure EMS to generate excitons, and if (e.g., when) excitons transition and decay from an excited state to a ground state, light may be generated. The luminance of light may be determined according to an amount of a current flowing through the emission layer. According to the configuration of the emission layer, a wavelength range of generated light may be determined.

The encapsulation layer TFE may be on (e.g., arranged on) the cathode CE. The encapsulation layer TFE may cover the light-emitting element layer LDL and/or the pixel circuit layer PCL. The encapsulation layer TFE may be configured to prevent or reduce oxygen and/or moisture from penetrating into the light-emitting element layer LDL. In one or more embodiments, the encapsulation layer TFE may include a structure in which one or more inorganic layers and one or more organic layers are alternately stacked. For example, the inorganic layer may include silicon nitride, silicon oxide, and/or silicon oxynitride (SiOₓN_{y}). The organic layer may include an organic insulating material such as a polyacrylate resin, an epoxy resin, a phenolic resin, a polyamide resin, a polyimide resin, an unsaturated polyester resin, a polyphenylene ether resin, a polyphenylene sulfide resin, or a benzocyclobutene (BCB)-based resin, or a (e.g., any suitable) combination thereof. However, the materials of the organic and inorganic layers of the encapsulation layer TFE are not limited thereto.

In order to improve the encapsulation efficiency of the encapsulation layer TFE, in one or more embodiments, the encapsulation layer TFE may further include a thin film including aluminum oxide (AlOₓ). The thin film including aluminum oxide may be positioned on an upper surface of the encapsulation layer TFE adjacent to (e.g., facing) the optical functional layer OFL and/or on a lower surface of the encapsulation layer TFE adjacent to (e.g., facing) the light-emitting element layer LDL.

The thin film including aluminum oxide maybe formed through atomic layer deposition (ALD). However, embodiments of the present disclosure are not limited thereto. In one or more embodiments, the encapsulation layer TFE may further include a thin film made of at least one selected from among one or more materials suitable for improving encapsulation efficiency.

The optical functional layer OFL may be on (e.g., arranged on) the encapsulation layer TFE. The optical functional layer OFL may include a color filter layer CFL and a lens array LA.

The color filter layer CFL may be arranged between the encapsulation layer TFE and the lens array LA. The color filter layer CFL may be configured to filter light emitted from the emission structure EMS to selectively output light in a wavelength range or with a color corresponding to each subpixel. The color filter layer CFL may include color filters CF corresponding to the first to third subpixels SP1 to SP3, and each of the color filters CF may be to transmit light in a wavelength range corresponding to a corresponding subpixel. For example, in one or more embodiments, the color filter corresponding to the first subpixel SP1 may be to transmit red color light, the color filter corresponding to the second subpixel SP2 may be to transmit green color light, and the color filter corresponding to the third subpixel SP3 may be to transmit blue color light. In one or more embodiments, according to light emitted from the emission structure EMS of each subpixel, at least some of the color filters CF may not be provided.

The lens array LA may be on (e.g., arranged on) the color filter layer CFL. The lens array LA may include lenses LS corresponding to the first to third subpixels SP1 to SP3, respectively. Each of the lenses LS may improve light output efficiency by outputting light emitted from the emission structure EMS through an intended path. The lens array LA may have a relatively high refractive index. For example, in one or more embodiments, the lens array LA may have a higher refractive index than the overcoat layer OC. In one or more embodiments, the lenses LS may include an organic material. In one or more embodiments, the lenses LS may include an acrylate material. However, the material of the lenses LS is not limited thereto.

In one or more embodiments, relative to the opening OP of the pixel defining layer PDL, at least some of the color filters CF of the color filter layer CFL and at least some of the lenses LS of the lens array LA may be shifted in a direction parallel to a plane defined by the first and second directions DR1 and DR2. For example, in one or more embodiments, in a central area of the display area DA, a center of the color filter and a center of the lens may be aligned with or overlap a center of the opening OP of the corresponding pixel defining layer PDL if (e.g., when) viewed in the third direction DR3. For example, in the central area of the display area DA, the opening OP of the pixel defining layer PDL may completely overlap the corresponding color filter of the color filter layer CFL and the corresponding lens of the lens array LA. In an area of the display area DA adjacent to the non-display area NDA, the center of the color filter and the center of the lens may be shifted in a plane direction from the center of the opening OP of the corresponding pixel defining layer PDL if (e.g., when) viewed in the third direction DR3. For example, in the area of the display area DA adjacent to the non-display area NDA, the opening OP of the pixel defining layer PDL may partially overlap the corresponding color filter of the color filter layer CFL and the corresponding lens of the lens array LA. Accordingly, at a central portion of the display area DA, light emitted from the emission structure EMS may be efficiently output in a normal direction of a display surface. At a peripheral portion of the display area DA, light emitted from the emission structure EMS may be efficiently output in a direction inclined by a certain angle with respect to the normal direction of the display surface.

The overcoat layer OC may be on (e.g., arranged on) the lens array LA. The overcoat layer OC may cover the optical functional layer OFL, the encapsulation layer TFE, the emission structure EMS, and/or the pixel circuit layer PCL. The overcoat layer OC may include one or more suitable materials suitable for protecting layers below the overcoat layer OC from foreign materials such as dust and moisture. For example, in one or more embodiments, the overcoat layer OC may include at least one of an inorganic insulating film or an organic insulating film. For example, in one or more embodiments, the overcoat layer OC may include epoxy, but embodiments of the present disclosure are not limited thereto. The overcoat layer OC may have a lower refractive index than the lens array LA.

The filling layer FIL may be on (e.g., arranged on) the overcoat layer OC. The filling layer FIL may be arranged on the display part DPP to provide a display surface and/or an input surface of the display panel DP (or a display device DD). The filling layer FIL may be a component arranged on an uppermost layer of the display part DPP in the display area DA and may protect the display part DPP from an external impact and/or the like. The filling layer FIL may have a viscosity of a certain level or more and may be made of a transparent curable resin.

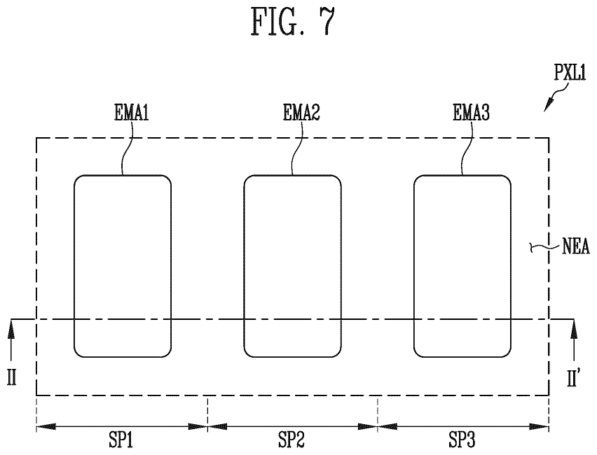

FIG. 7 is a schematic plan view illustrating one of the pixels of FIG. 6 according to one or more embodiments of the present disclosure. In FIG. 7, for clear and concise description, the first pixel PXL1 among the first and second pixels PXL1 and PXL2 of FIG. 6 is schematically shown. The remaining pixels may be provided similarly to the first pixel PXL1.

Referring to FIGS. 6 and 7, the first pixel PXL1 may include a first subpixel SP1, a second subpixel SP2, and a third subpixel SP3 arranged in a first direction DR1.

The first subpixel SP1 may include a first emission area EMA1 and a non-emission area NEA around the first emission area EMA1. The second subpixel SP2 may include a second emission area EMA2 and a non-emission area NEA around the second emission area EMA2. The third subpixel SP3 may include a third emission area EMA3 and a non-emission area NEA around the third emission area EMA3.

The first emission area EMA1 may be an area in which light is emitted from a portion of an emission structure EMS (see FIG. 6) corresponding to the first subpixel SP1. The second emission area EMA2 may be an area in which light is emitted from a portion of the emission structure EMS corresponding to the second subpixel SP2. The third emission area EMA3 may be an area in which light is emitted from a portion of the emission structure EMS corresponding to the third subpixel SP3. As described with reference to FIG. 6, each emission area may be understood as an opening OP of a pixel defining layer corresponding to each of the first to third subpixels SP1 to SP3.

In one or more embodiments, the first subpixel SP1, the second subpixel SP2, and the third subpixel SP3 may have substantially the same area, but embodiments of the present disclosure are not limited thereto. According to one or more embodiments, the second subpixel SP2 may have a larger area than the first subpixel SP1, and the third subpixel SP3 may have a larger area than the second subpixel SP2.

The first subpixel SP1, the second subpixel SP2, and the third subpixel SP3 may have a polygonal shape. For example, in one or more embodiments, the first subpixel SP1, the second subpixel SP2, and the third subpixel SP3 may each independently have a quadrangular shape or a hexagonal shape, but embodiments of the present disclosure are not limited thereto. According to one or more embodiments, the first subpixel SP1, the second subpixel SP2, and the third subpixel SP3 may each independently have a circular shape, a semi-elliptical shape, and/or the like.

The arrangement of the subpixels shown in FIG. 7 is illustrative, and embodiments of the present disclosure are not limited thereto. Each pixel PXL may include two or more subpixels, the subpixels may be arranged in one or more suitable ways, each of the subpixels may have one or more suitable shapes, and each of emission areas of the subpixels may also have one or more suitable shapes.

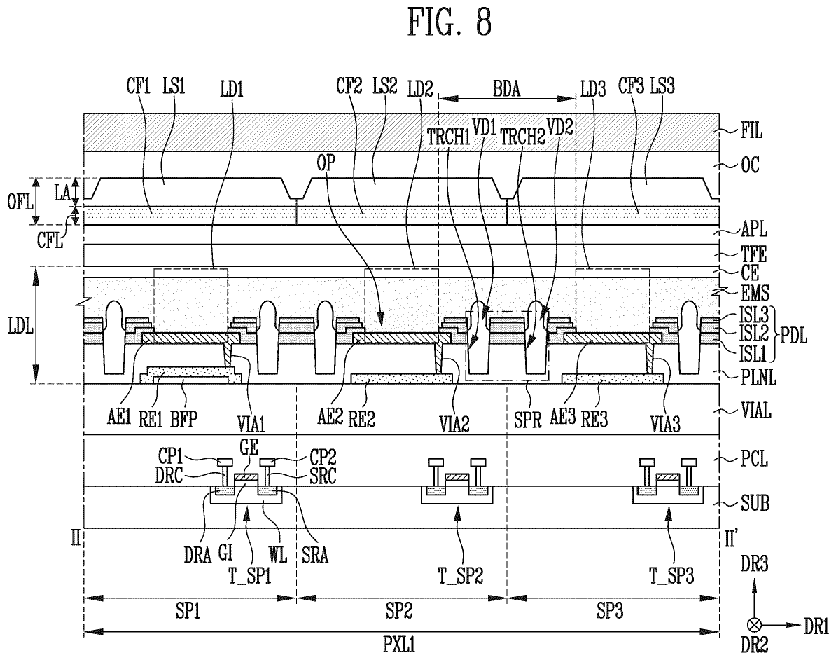

FIG. 8 is a schematic cross-sectional view taken along the line II-II′ of FIG. 7.

Referring to FIGS. 7 and 8, in one or more embodiments, a first pixel PXL1 may include a first subpixel SP1, a second subpixel SP2, and a third subpixel SP3.

Each of the first to third subpixels SP1 to SP3 may include a substrate SUB and a pixel circuit layer PCL on (e.g., arranged on) the substrate SUB.

In one or more embodiments, the substrate SUB may include a silicon wafer substrate formed using a semiconductor process. For example, in one or more embodiments, the substrate SUB may include silicon, germanium, and/or silicon-germanium.

The pixel circuit layer PCL may be arranged on the substrate SUB. The substrate SUB and the pixel circuit layer PCL may include circuit elements of each of the first to third subpixels SP1 to SP3. For example, in one or more embodiments, the substrate SUB and the pixel circuit layer PCL may include a transistor T_SP1 of the first subpixel SP1, a transistor T_SP2 of the second subpixel SP2, and a transistor T_SP3 of the third subpixel SP3. The transistor T_SP1 of the first subpixel SP1 may be one of transistors included in a subpixel circuit of the first subpixel SP1, the transistor T_SP2 of the second subpixel SP2 may be one of transistors included in a subpixel circuit of the second subpixel SP2, and the transistor T_SP3 of the third subpixel SP3 may be one of transistors included in a subpixel circuit of the third subpixel SP3. In FIG. 8, for clear and concise description, one of the transistors of each subpixel is shown, and the remaining circuit elements are omitted for not obscuring the description.

The transistor T_SP1 of the first subpixel SP1 may include a source region SRA, a drain region DRA, and a gate electrode GE.

The source region SRA and the drain region DRA may be arranged in the substrate SUB. A well WL may be arranged in the substrate SUB through an ion implantation process, and the source region SRA and the drain region DRA may be arranged to be spaced and/or apart (e.g., spaced apart or separated) from each other in the well WL. A region between the source region SRA and the drain region DRA in the well WL may be defined as a channel region.

The gate electrode GE overlaps the channel region between the source region SRA and the drain region DRA and may be arranged on the pixel circuit layer PCL. The gate electrode GE may be spaced and/or apart (e.g., spaced apart or separated) from the well WL or the channel region by an insulating material of a gate insulating layer GI and/or the like. The gate electrode GE may include a conductive material (e.g., electrically conductive material or electron conductor).

A plurality of layers included in the pixel circuit layer PCL may include insulating layers and conductive patterns arranged between the insulating layers. The conductive patterns may include a first conductive pattern CP1 and a second conductive pattern CP2. The first conductive pattern CP1 may be electrically connected to the drain region DRA through a drain connection portion DRC that passes through one or more insulating layers. The second conductive pattern CP2 may be electrically connected to the source region SRA through a source connection portion SRC that passes through one or more insulating layers.

The gate electrode GE and the first and second conductive patterns CP1 and CP2 may be electrically connected to other circuit elements and/or interconnects, the transistor T_SP1 of the first subpixel SP1 may be provided as one of the transistors constituting the subpixel circuit of first subpixel SP1.

Each of the transistor T_SP2 of the second subpixel SP2 and the transistor T_SP3 of the third subpixel SP3 may be provided to be substantially the same as the transistor T_SP1 of the first subpixel SP1.

As described above, the substrate SUB and the pixel circuit layer PCL may include the circuit elements of each of the first to third subpixels SP1 to SP3.

A via layer VIAL may be on (e.g., arranged on) the pixel circuit layer PCL. The via layer VIAL may cover the pixel circuit layer PCL and may have an overall flat (or substantially uniform) surface. The via layer VIAL may include at least one selected from among silicon oxide (SiOₓ), silicon nitride (SiNₓ), and silicon carbon nitride (SiCN), but embodiments of the present disclosure are not limited thereto.

A light-emitting element layer LDL may be on (e.g., arranged on) the via layer VIAL. The light-emitting element layer LDL may include first to third reflective electrodes RE1 to RE3, a planarization layer PLNL, first to third anodes AE1 to AE3, a pixel defining layer PDL, an emission structure EMS, and a cathode CE.

On the via layer VIAL, the first to third reflective electrodes RE1 to RE3 may be arranged in the first to third subpixels SP1 to SP3, respectively. For example, the first reflective electrode RE1 may be arranged on the via layer VIAL of the first subpixel SP1, the second reflective electrode RE2 may be arranged on the via layer VIAL of the second subpixel SP2, and the third reflective electrode RE3 may be arranged on the via layer VIAL of the third subpixel SP3. Each of the first to third reflective electrodes RE1 to RE3 may be in contact with a circuit element arranged on the pixel circuit layer PCL through a via passing through the via layer VIAL.

The first to third reflective electrodes RE1 to RE3 may each function as a full mirror that reflects light emitted from the emission structure EMS toward a display screen (or a filling layer FIL). The first to third reflective electrodes RE1 to RE3 may include metal materials (e.g., may each independently include a metal) suitable for reflecting light. For example, in one or more embodiments, the first to third reflective electrodes RE1 to RE3 may each independently include at least one selected from among aluminum, silver, magnesium, platinum, palladium, gold, nickel, neodymium, iridium, chromium, and titanium or may each independently include at least one selected from among alloys of two or more materials thereof. However, the materials of the first to third reflective electrodes RE1 to RE3 are not limited to the above-described embodiments.

The first reflective electrode RE1, the second reflective electrode RE2, and the third reflective electrode RE3 may each have substantially the same thickness. For example, in one or more embodiments, the thickness of each of the first reflective electrode RE1, the second reflective electrode RE2, and the third reflective electrode RE3 may be in a range of about 700 Å to about 1,000 Å, but embodiments of the present disclosure are not limited thereto.

According to one or more embodiments, a connection electrode may be arranged below each of the first to third reflective electrodes RE1 to RE3. The connection electrode may be provided to improve the electrical connection characteristics between the corresponding reflective electrode and the circuit element of the pixel circuit layer PCL. The connection electrode may include multiple layers. For example, in one or more embodiments, the multiple layers may include a stacked structure of titanium/titanium nitride (or titanium nitride)/tantalum nitride (or tantalum nitride), but embodiments of the present disclosure are not limited thereto. According to one or more embodiments, the corresponding reflective electrode may be arranged between the layers constituting the connection electrode.

In one or more embodiments, a buffer pattern BFP may be arranged below at least one of the first to third reflective electrodes RE1 to RE3. For example, in one or more embodiments, the buffer pattern BFP may be arranged between the first reflective electrode RE1 and the via layer VIAL. The buffer pattern BFP may include an inorganic material such as silicon carbon nitride, but embodiments of the present disclosure are not limited thereto. The buffer pattern BFP may be arranged, thereby adjusting a height of the corresponding reflective electrode in a third direction DR3. For example, in one or more embodiments, the buffer pattern BFP may adjust a height of the first reflective electrode RE1 between the first reflective electrode RE1 and the via layer VIAL. The first reflective electrode RE1 may cover the entire buffer pattern BFP by covering all of an upper surface and both (e.g., simultaneously) side surfaces (or both (e.g., simultaneously) ends) of the buffer pattern BFP. One area of the first reflective electrode RE1 may extend to an upper surface of the via layer VIAL which in contact with both (e.g., simultaneously) side surfaces of the buffer pattern BFP.

In one or more embodiments, in the second subpixel SP2, the above-described buffer pattern BFP may not be arranged between the second reflective electrode RE2 and the via layer VIAL, and the second reflective electrode RE2 may be arranged directly on the via layer VIAL. In addition, in the third subpixel SP3, the above-described buffer pattern BFP may not be arranged between the third reflective electrode RE3 and the via layer VIAL, and the third reflective electrode RE3 may be arranged directly on the via layer VIAL.

The first to third reflective electrodes RE1 to RE3 may each function as a full mirror, and the cathode CE may function as a half mirror. Light emitted from the emission structure EMS may be amplified by at least partially reciprocating between the corresponding reflective electrode and the cathode CE, and the amplified light may be output through the cathode CE. In this way, a distance between each reflective electrode and the cathode CE may be understood as a resonance distance for light emitted from an emission layer of the corresponding emission structure EMS.

In one or more embodiments, the first subpixel SP1 may have a shorter resonance distance than other subpixels (for example, the second and third subpixels SP2 and SP3) due to the buffer pattern BFP. The resonance distance adjusted in this way may allow light in a specific wavelength range (for example, a red color) to be effectively and efficiently amplified. Accordingly, the first subpixel SP1 may effectively and efficiently output light in a corresponding wavelength range.

In FIG. 8, the buffer pattern BFP is shown as being provided in the first subpixel SP1 and not being provided in the second and third subpixels SP2 and SP3, but embodiments of the present disclosure are not limited thereto. According to one or more embodiments, the buffer pattern may also be provided in at least one selected from among the second and third subpixels SP2 and SP3 to adjust a resonance distance of the at least one selected from among the second and third subpixels SP2 and SP3. For example, in one or more embodiments, the first subpixel SP1 is a red subpixel, the second subpixel SP2 is a green subpixel, and the third subpixel SP3 is a blue subpixel, a distance between the first reflective electrode RE1 and the cathode CE may be shorter than a distance between the second reflective electrode RE2 and the cathode CE, and the distance between the second reflective electrode RE2 and the cathode CE may be shorter than a distance between the third reflective electrode RE3 and the cathode CE.

A thickness of the buffer pattern BFP (or a thickness in the third direction DR3) may be in a range of about 400 Å to about 600 Å, but embodiments of the present disclosure are not limited thereto.

The planarization layer PLNL may be provided to planarize stepped portions between the first to third reflective electrodes RE1 to RE3. The planarization layer PLNL may be on (e.g., arranged on) the via layer VIAL and the first to third reflective electrodes RE1 to RE3. The planarization layer PLNL may entirely cover the first to third reflective electrodes RE1 to RE3 and the via layer VIAL and may have a flat surface. The planarization layer PLNL may include an insulating material. For example, in one or more embodiments, the planarization layer PLNL may include an inorganic material such as silicon oxide (SiOₓ) and/or silicon nitride (SiNₓ), but embodiments of the present disclosure are not limited thereto. According to one or more embodiments, the planarization layer PLNL may not be provided.

In one or more embodiments, the planarization layer PLNL may include a via that exposes one area of the reflective electrode. For example, in one or more embodiments, the planarization layer PLNL may include a first via VIA1 exposing one area of the first reflective electrode RE1, a second via VIA2 exposing one area of the second reflective electrode RE2, and a third via VIA3 exposing one area of the third reflective electrode RE3.

The first anode AE1, the second anode AE2, and the third anode AE3 may each be arranged on the planarization layer PLNL. For example, in one or more embodiments, the first anode AE1 may be arranged on the planarization layer PLNL to overlap the first reflective electrode RE1, the second anode AE2 may be arranged on the planarization layer PLNL to overlap the second reflective electrode RE2, and the third anode AE3 may be arranged on the planarization layer PLNL to overlap the third reflective electrode RE3.

The first to third anodes AE1 to AE3 may respectively have a shape similar to the first to third emission areas EMA1 to EMA3 of FIG. 7 if (e.g., when) viewed in the third direction DR3.

Each of the first to third anodes AE1 to AE3 may be electrically connected to a corresponding reflective electrode. For example, the first anode AE1 may be electrically connected to the first reflective electrode RE1 through the first via VIA1 passing through the planarization layer PLNL. The second anode AE2 may be electrically connected to the second reflective electrode RE2 through the second via VIA2 passing through the planarization layer PLNL. The third anode AE3 may be electrically connected to the third reflective electrode RE3 through the third via VIA3 passing through the planarization layer PLNL.

The first to third anodes AE1 to AE3 may each independently include at least one selected from among transparent conductive materials such as indium tin oxide (ITO), indium zinc oxide (IZO), zinc oxide (ZnOₓ), indium gallium zinc oxide (IGZO), and indium tin zinc oxide (ITZO). However, the materials of the first to third anodes AE1 to AE3 are not limited thereto. For example, in one or more embodiments, the first to third anodes AE1 to AE3 may include titanium nitride.

In one or more embodiments, the first to third anodes AE1 to AE3 may have substantially the same thickness. For example, the thickness of each of the first anode AE1, the second anode AE2, and the third anode AE3 may be in a range of about 700 Å to about 1,000 Å, but embodiments of the present disclosure are not limited thereto.

In one or more embodiments, insulating layers for adjusting the height of one or more of the first to third anodes AE1 to AE3 may be further provided. The insulating layers may be arranged between one or more of the first to third anodes AE1 to AE3 and the corresponding reflective electrodes. In these embodiments, the planarization layer PLNL and/or the buffer pattern BFP may not be provided.

The pixel defining layer PDL may be arranged on portions of the first to third anodes AE1 to AE3 and the planarization layer PLNL. The pixel defining layer PDL may include an opening OP exposing a portion of each of the first to third anodes AE1 to AE3. The opening OP of the pixel defining layer PDL may define the emission area of each of the first to third subpixels SP1 to SP3. The pixel defining layer PDL may be arranged in a non-emission area NEA (see FIG. 7) to define the first emission area EMA1, the second emission area EMA2, and the third emission area EMA3 described with reference to FIG. 7.

In one or more embodiments, the pixel defining layer PDL may include a plurality of inorganic insulating layers. Each of the plurality of inorganic insulating layers may include at least one selected from among silicon oxide and silicon nitride. For example, in one or more embodiments, the pixel defining layer PDL may include a first inorganic insulating layer ISL1, a second inorganic insulating layer ISL2, and a third inorganic insulating layer ISL3 sequentially stacked. The first to third inorganic insulating layers ISL1 to ISL3 may each independently include at least one selected from among silicon nitride, silicon oxide, and silicon oxynitride. However, the material of the pixel defining layer PDL is not limited to the above-described embodiments. In one or more embodiments, the first to third inorganic insulating layers ISL1 to ISL3 may have a step-shaped cross section in an area adjacent to the opening OP of the pixel defining layer PDL.

The pixel defining layer PDL may include a separator SPR in a boundary area BDA between adjacent subpixels. For example, the separator SPR may be provided in each of the boundary areas between the subpixels SP of FIG. 5.

The separator SPR may cause a discontinuous portion to be formed in the boundary area BDA in the emission structure EMS. For example, in one or more embodiments, the emission structure EMS may be disconnected or bent in the boundary area BDA due to the separator SPR. Accordingly, the first to third emission areas EMA1 to EMA3 of FIG. 7 corresponding to the first to third subpixels SP1 to SP3 may be defined along the separator SPR of the pixel defining layer PDL.

The separator SPR may be provided in or on the pixel defining layer PDL. In one or more embodiments, the pixel defining layer PDL may include one or more trenches TRCH1 and TRCH2 as the separator SPR in the boundary area BDA. In one or more embodiments, as shown in FIG. 8, one or more trenches TRCH1 and TRCH2 may pass through the pixel defining layer PDL and partially pass through the planarization layer PLNL. In one or more embodiments, one or more trenches TRCH1 and TRCH2 may pass through the pixel defining layer PDL and the planarization layer PLNL and may partially pass through the via layer VIAL. In one or more embodiments, one or more trenches TRCH1 and TRCH2 at least partially penetrate the planarization layer PLNL and/or via layer VIAL, and a portion of the pixel defining layer PDL may be arranged within one or more trenches TRCH1 and TRCH2.

In FIG. 8, two trenches TRCH1 and TRCH2, for example, a first trench TRCH1 and a second trench TRCH2, are shown as being provided in the boundary area BDA, but embodiments of the present disclosure are not limited thereto. For example, in one or more embodiments, the pixel defining layer PDL may include one trench or three or more trenches in the boundary area BDA.

Due to the first and second trenches TRCH1 and TRCH2, discontinuous portions such as a first void VD1 and a second void VD2 may be formed in the boundary area BDA in the emission structure EMS. Some of a plurality of layers stacked in the emission structure EMS may be disconnected or bent by the first and second voids VD1 and VD2. For example, in one or more embodiments, at least one charge generation layer and at least one hole injection layer included in the emission structure EMS may be disconnected at the first and second voids VD1 and VD2. As such, portions of the emission structure EMS included in the first to third subpixels SP1 to SP3 may be at least partially separated due to the first and second trenches TRCH1 and TRCH2.

According to shapes of the first and second trenches TRCH1 and TRCH2, the discontinuous portions formed in the emission structure EMS may be variously modified.

In one or more embodiments, the emission structure EMS may be formed through a process including vacuum deposition, inkjet printing, and/or the like. In these embodiments, the same materials as the emission structure EMS may be positioned on bottom surfaces of the first and second trenches TRCH1 and TRCH2 adjacent to the via layer VIAL.

In one or more embodiments, the pixel defining layer PDL may include an additional separator such that the emission structure EMS further includes a discontinuous portion adjacent to the boundary area BDA. In one or more embodiments, the third inorganic insulating layer ISL3 at the uppermost side among the first to third inorganic insulating layers ISL1 to ISL3 of the pixel defining layer PDL may have a wider width than the second inorganic insulating layer ISL2 arranged immediately below the third inorganic insulating layer ISL3. For example, the pixel defining layer PDL may have a “T”-shaped or “I”-shaped cross section in the boundary area BDA. According to a shape of the pixel defining layer PDL, the plurality of layers included in the emission structure EMS may be at least partially disconnected or bent in the boundary area BDA or an area adjacent to the boundary area BDA.

The emission structure EMS may be on (e.g., arranged on) the anodes AE exposed by the opening OP of the pixel defining layer PDL. The emission structure EMS fills the opening OP of the pixel defining layer PDL and may be entirely arranged over the first to third subpixels SP1 to SP3. As previously described, the emission structure EMS may be at least partially disconnected or bent in the boundary area BDA by the separator SPR. Accordingly, in case that the display panel DP is operated, a current leaking from each of the first to third subpixels SP1 to SP3 to the subpixels adjacent thereto through the layers included in the emission structure EMS may be reduced. Accordingly, first to third light-emitting elements LD1 to LD3 may operate with relatively high reliability.

The cathode CE may be on (e.g., arranged on) the emission structure EMS. The cathode CE may be commonly provided to the first to third subpixels SP1 to SP3. The cathode CE may function as a half mirror that partially transmits and partially reflects light emitted from the emission structure EMS.

The first anode AE1, a portion of the emission structure EMS overlapping the first anode AE1, and a portion of the cathode CE overlapping the first anode AE1 may constitute the first light-emitting element LD1. The second anode AE2, a portion of the emission structure EMS overlapping the second anode AE2, and a portion of the cathode CE overlapping the second anode AE2 may constitute the second light-emitting element LD2. The third anode AE3, a portion of the emission structure EMS overlapping the third anode AE3, and a portion of the cathode CE overlapping the third anode AE3 may constitute the third light-emitting element LD3.

An encapsulation layer TFE may be on (e.g., arranged) on the cathode CE. The encapsulation layer TFE may prevent or reduce oxygen and/or moisture from penetrating into the light-emitting element layer LDL.

An optical functional layer OFL may be on (e.g., arranged on) the encapsulation layer TFE. In one or more embodiments, the optical functional layer OFL may be attached to the encapsulation layer TFE through an adhesive layer APL. For example, the optical functional layer OFL may be manufactured separately and attached to the encapsulation layer TFE through the adhesive layer APL. The adhesive layer APL may further perform a function of protecting lower layers including the encapsulation layer TFE.

The optical functional layer OFL may include a color filter layer CFL and a lens array LA.

The color filter layer CFL may include first to third color filters CF1 to CF3 respectively corresponding to the first to third subpixels SP1 to SP3. For example, in one or more embodiments, the color filter layer CFL may include the first color filter CF1 corresponding to the first subpixel SP1, the second color filter CF2 corresponding to the second subpixel SP2, and the third color filter CF3 corresponding to the third subpixel SP3. The first to third color filters CF1 to CF3 may light (e.g., transmit) pieces of light in different wavelength ranges. For example, in one or more embodiments, the first color filter CF1 may be to transmit red color light, the second color filter CF2 may be to transmit green color light, and the third color filter CF3 may be to transmit blue color light. In these embodiments, the first subpixel SP1 may be a red subpixel, the second subpixel SP2 may be a green subpixel, and the third subpixel SP3 may be a blue subpixel.

In one or more embodiments, the first to third color filters CF1 to CF3 may partially overlap each other in the boundary area BDA. In one or more embodiments, the first to third color filters CF1 to CF3 may be spaced and/or apart (e.g., spaced apart or separated) from each other, and a black matrix may be provided between the first to third color filters CF1 to CF3 spaced and/or apart (e.g., spaced apart or separated) from each other.

The lens array LA may be on (e.g., arranged on) the color filter layer CFL. The lens array LA may include first to third lenses LS1 to LS3 respectively corresponding to the first to third subpixels SP1 to SP3. For example, the lens array LA may include the first lens LS1 corresponding to the first subpixel SP1, the second lens LS2 corresponding to the second subpixel SP2, and the third lens LS3 corresponding to the third subpixel SP3. The first to third lenses LS1 to LS3 may each improve light output efficiency by outputting light emitted from the first to third light-emitting elements LD1 to LD3 along an intended path.

An overcoat layer OC may be on (e.g., arranged on) the lens array LA. The overcoat layer OC is configured to protect lower layers below the overcoat layer OC from foreign materials such as dust and moisture. A filling layer FIL may be on (e.g., arranged on) the overcoat layer OC.

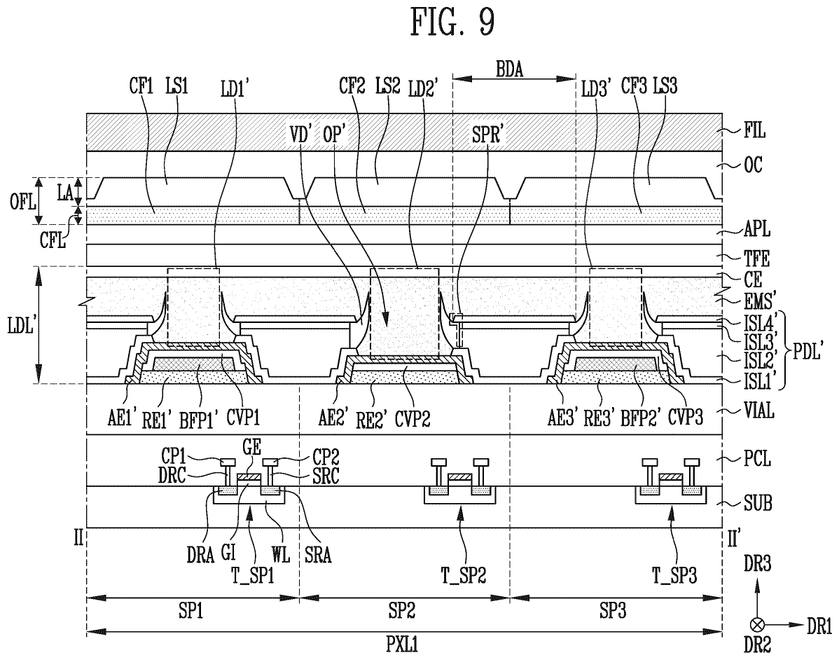

FIG. 9 is a schematic cross-sectional view taken along the lines II-II′ of FIG. 7 according to one or more embodiments of the present disclosure.

Referring to FIGS. 7 and 9, a pixel circuit layer PCL and a via layer VIAL are on (e.g., arranged on) a substrate SUB. The substrate SUB, the pixel circuit layer PCL, and the via layer VIAL of FIG. 9 may be provided similarly to the substrate SUB, the pixel circuit layer PCL, and the via layer VAL described with reference to FIG. 8. Hereinafter, redundant descriptions will not be provided.

A light-emitting element layer LDL′ may be on (e.g., arranged on) the via layer VIAL. The light-emitting element layer LDL′ may include first to third reflective electrodes RE1′ to RE3′, first and second buffer patterns BFP1′ and BFP2′, and first to third cover patterns CVP1 to CVP3, first to third anodes AE1′ to AE3′, a pixel defining layer PDL′, an emission structure EMS′, and a cathode CE.

On the via layer VIAL, the first to third reflective electrodes RE1′ to RE3′ may be arranged in first to third subpixels SP1 to SP3, respectively. Each of the first to third reflective electrodes RE1′ to RE3′ may be in contact with a circuit element arranged on the pixel circuit layer PCL through a via passing through the via layer VIAL.

The first to third reflective electrodes RE1′ to RE3′ are each configured to reflect light emitted from the emission structure EMS' toward a display screen (or a filling layer FIL). The first to third reflective electrodes RE1′ to RE3′ may include metal materials suitable for reflecting light.

In one or more embodiments, a connection electrode may be further provided between each of the first to third reflective electrodes RE1′ to RE3′ and the via layer VIAL. The connection electrode may improve the electrical connection characteristics between the corresponding reflective electrode and the circuit element of the pixel circuit layer PCL.

A buffer pattern may be arranged on at least one selected from among the first to third reflective electrodes RE1′ to RE3′. In one or more embodiments, the first and second buffer patterns BFP1′ and BFP2′ may be arranged on the first and third reflective electrodes RE1′ and RE3′, respectively. Heights of the first and third anodes AE1′ and AE3′ in a third direction DR3 may be adjusted by the first and second buffer patterns BFP1′ and BFP2′, respectively. The first and second buffer patterns BFP1′ and BFP2′ may each independently include at least one selected from among inorganic materials such as silicon oxide (SiOₓ) and silicon nitride (SiNₓ), but embodiments of the present disclosure are not limited thereto.

The first to third cover patterns CVP1 to CVP3 may be arranged on the first to third reflective electrodes RE1′ to RE3′, respectively. In the first subpixel SP1, the first cover pattern CVP1 is arranged on the first reflective electrode RE1′ and the first buffer pattern BFP1′. In the second subpixel SP2, the second cover pattern CVP2 is arranged on the second reflective electrode RE2′. In the third subpixel SP3, the third cover pattern CVP3 is arranged on the third reflective electrode RE3′ and the second buffer pattern BFP2′. The first to third cover patterns CVP1 to CVP3 may be formed after the first and second buffer patterns BFP1′ and BFP2′ are formed during a manufacturing process. The first to third cover patterns CVP1 to CVP3 may each include the same material as the first and second buffer patterns BFP1′ and BFP2′. For example, in one or more embodiments, the first to third cover patterns CVP1 to CVP3 may each independently include at least one selected from among inorganic materials such as silicon oxide (SiOₓ) and silicon nitride (SiNₓ), but embodiments of the present disclosure are not limited thereto.

The first to third anodes AE1′ to AE3′ are respectively arranged on the first to third cover patterns CVP1 to CVP3. In one or more embodiments, the first anode AE1′ may cover the first cover pattern CVP1, the first buffer pattern BFP1′, and the first reflective electrode RE1′. The second anode AE2′ may cover the second cover pattern CVP2 and the second reflective electrode RE2′. The third anode AE3′ may cover the third cover pattern CVP3, the second buffer pattern BFP2′, and the third reflective electrode RE3′.

The first to third anodes AE1′ to AE3′ may be electrically connected to the first to third reflective electrodes RE1′ to RE3′, respectively. For example, in one or more embodiments, each anode may be connected to an end (or an edge) of a corresponding reflective electrode. However, embodiments of the present disclosure are not limited thereto. In order to improve the electrical connection characteristics between an anode and a reflective electrode, the anode may be connected to the reflective electrode in one or more suitable ways.

The first to third anodes AE1′ to AE3′ and the cathode CE may partially reflect incident light. Light emitted from an emission layer of the emission structure EMS' may be amplified by reciprocating between the corresponding anode and the cathode CE and may be output through the cathode CE. For example, in one or more embodiments, each anode and the cathode CE may provide a resonance structure in a corresponding subpixel. In these embodiments, a distance between each anode and the cathode CE may be understood as a resonance distance for light emitted from the emission layer of the corresponding emission structure EMS′.

In one or more embodiments, the first to third subpixels SP1 to SP3 may correspond to red, green, and blue, respectively. In these embodiments, heights of the first and third anodes AE1′ and AE3′ in the third direction DR3 may be greater than a height of the second anode AE2′ by the first and second buffer patterns BFP1′ and BFP2′, respectively. Accordingly, the first and third subpixels SP1 and SP3 may have a shorter resonance distance than the second subpixel SP2 due to the first and second buffer patterns BFP1′ and BFP2′. In this way, a resonance distance of each subpixel may be adjusted such that light in a wavelength range of a corresponding color is effectively and efficiently amplified.

In FIG. 9, the first and second buffer patterns BFP1′ and BFP2′ are shown as being arranged below the first and third anodes AE1′ and AE3′, respectively, but embodiments of the present disclosure are not limited thereto. For example, in one or more embodiments, one selected from among the first and second buffer patterns BFP1′ and BFP2′ may not be provided. In one or more embodiments, both (e.g., simultaneously) the first and second buffer patterns BFP1′ and BFP2′ may not be provided. In these embodiments, resonance distances between the anodes and the cathode CE may be the same. In one or more embodiments, a buffer pattern may be arranged below each of the first to third anodes AE1′ to AE3′. In these embodiments, the buffer patterns arranged below the anodes may have different thicknesses, and thus the resonance distances between the anodes and the cathode CE may be different. In this way, the buffer pattern may be provided below at least one of the first to third anodes AE1′ to AE3′ to adjust a height of the corresponding anode, thereby improving or optimizing a resonance distance in each subpixel.

The pixel defining layer PDL′ is on (e.g., arranged on) portions of the first to third anodes AE1′ to AE3′ and the via layer VIAL. The pixel defining layer PDL has an opening OP′ exposing a portion of each of the first to third anodes AE1′ to AE3′. An area overlapping the pixel defining layer PDL′ may be understood as a boundary area BDA between adjacent subpixels.

In one or more embodiments, the pixel defining layer PDL′ may include first to fourth inorganic insulating layers ISL1′ to ISL4′. The first inorganic insulating layer ISL1′ may cover portions of the first to third anodes AE1′ to AE3′ and the via layer VIAL. The second inorganic insulating layer ISL2′ is arranged on the first inorganic insulating layer ISL1′, the third inorganic insulating layer ISL3′ is arranged on the second inorganic insulating layer ISL2′, and the fourth inorganic insulating layer ISL4′ is arranged on the third inorganic insulating layer ISL3′. The first and third inorganic insulating layers ISL1′ and ISL3′ may each include silicon nitride (SiNₓ), and the second and fourth inorganic insulating layers ISL2′ and ISL4′ may each include silicon oxide SiOₓ. However, embodiments of the present disclosure are not limited thereto. In one or more embodiments, the first inorganic insulating layer ISL1′ may not be provided.

The pixel defining layer PDL′ may include a separator SPR′ in the boundary area BDA between adjacent subpixels. The separator SPR′ may cause a discontinuous portion such as a void VD′ to be formed in the emission structure EMS′. Due to the discontinuous portion, at least some of a plurality of layers included in the emission structure EMS' may be disconnected or bent.

In one or more embodiments, the fourth inorganic insulating layer ISL4′ may be wider than the second and third inorganic insulating layers ISL2′ and ISL3′. In these embodiments, side surfaces of the second to fourth inorganic insulating layers ISL2′ to ISL4′ adjacent to the opening OP′ of the pixel defining layer PDL′ may be provided as the separator SPR′. A portion of the fourth inorganic insulating layer ISL4′ may have an eave shape on the second and third inorganic insulating layers ISL2′ and ISL3′.

In one or more embodiments, in the boundary area BDA, the second and third inorganic insulating layers ISL2′ and ISL3′ may have the same width. However, embodiments of the present disclosure are not limited thereto, and the second and third inorganic insulating layers ISL2′ and ISL3′ may have different widths.

In the second subpixel SP2, a portion of the fourth inorganic insulating layer ISL4′ and side surfaces of the second and third inorganic insulating layers ISL2′ and ISL3′ may be provided as the separator SPR′. Accordingly, the void VD′ may be formed adjacent to a portion of the fourth inorganic insulating layer ISL4′ in the emission structure EMS′.

Some of the plurality of layers stacked in the emission structure EMS' may be disconnected or bent due to the void VD′. For example, in one or more embodiments, at least one charge generation layer and at least one hole injection layer included in the emission structure EMS' may be disconnected by the void VD′. In this way, due to the separator SPR′, portions of the emission structure EMS' included in the first to third subpixels SP1 to SP3 may be at least partially separated from each other.

The pixel defining layer PDL′ may include an additional separator such that the emission structure EMS' further includes a discontinuous portion in the boundary area BDA. In one or more embodiments, the pixel defining layer PDL′ may include one or more trenches as the separator in the boundary area BDA. The trenches may pass through one or more of the first to fourth inorganic insulating layers ISL1′ to ISL4′. Due to the trenches, some of the plurality of layers stacked in the emission structure EMS′, for example, at least one charge generation layer and at least one hole injection layer, may be disconnected or bent. In one or more embodiments, the emission structure EML′ may have a structure in which three emission units each including an emission layer are stacked, and two charge generation layers may be arranged between the three emission units. In these embodiments, the pixel defining layer PDL′ may include one or more trenches in the boundary area BDA.

The emission structure EMS' may be on (e.g., arranged on) the anodes AE exposed by the opening OP′ of the pixel defining layer PDL′. The emission structure EMS' may be disconnected or bent in the boundary area BDA or an area adjacent to the boundary area BDA due to the separator SPR′. Accordingly, in case that a display panel DP is operated, a current leaking from each of the first to third subpixels SP1 to SP3 to the subpixels adjacent thereto through the layers included in the emission structure EMS' may be reduced. Accordingly, first to third light-emitting elements LD1′ to LD3′ may operate with relatively high reliability.

In one or more embodiments, the emission structure EMS' may include two emission units sequentially stacked, and each of the emission units may include an emission layer configured to generate light according to an applied current. In one or more embodiments, the emission structure EMS' may include three emission units sequentially stacked, and each of the emission units may include an emission layer configured to generate light according to an applied current. In these embodiments, the charge generation layer may be arranged between adjacent emission units.

In one or more embodiments, the emission structure EMS' may be formed through a process including vacuum deposition, inkjet printing, and/or the like.

The cathode CE may be on (e.g., arranged on) the emission structure (EMS′). The cathode CE may be commonly provided to the first to third subpixels SP1 to SP3.

An encapsulation layer TFE may be on (e.g., arranged on) the cathode CE. The encapsulation layer TFE may prevent or reduce oxygen and/or moisture from penetrating into the light-emitting element layer LDL′.

An adhesive layer APL, an optical functional layer OFL, an overcoat layer OC, and a filling layer FIL may be on (e.g., arranged on) the encapsulation layer TFE. The adhesive layer APL, the optical functional layer OFL, the overcoat layer OC, and the filling layer are provided similarly to the adhesive layer APL, the optical functional layer OFL, the overcoat layer OC, and the filling layer FIL of FIG. 8, respectively. Redundant descriptions thereof will not be provided herein for conciseness.

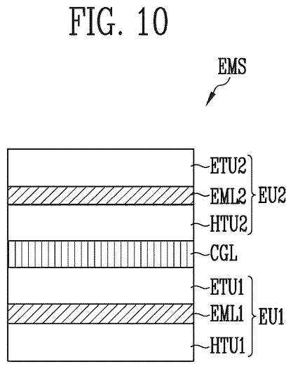

FIG. 10 is a schematic cross-sectional view illustrating an emission structure EMS included in one of the first to third light-emitting elements of FIG. 8 or 9 according to one or more embodiments of the present disclosure.

Referring to FIG. 10, the emission structure EMS may have a tandem structure in which a first emission unit EU1 and a second emission unit EU2 are stacked. The emission structure EMS may be provided to be substantially the same in the first to third light-emitting elements LD1 to LD3 of FIG. 8. In addition, the emission structure EMS may be provided to be substantially the same in the first to third light-emitting elements LD1′ to LD3′ of FIG. 9.

Each of the first and second emission units EU1 and EU2 may include at least one emission layer that generates light according to an applied current. The first emission unit EU1 may include a first emission layer EML1, a first electron transport unit ETU1, and a first hole transport unit HTU1. The first emission layer EML1 may be arranged between the first electron transport unit ETU1 and the first hole transport unit HTU1. The second emission unit EU2 may include a second emission layer EML2, a second electron transport unit ETU2, and a second hole transport unit HTU2. The second emission layer EML2 may be arranged between the second electron transport unit ETU2 and the second hole transport unit HTU2.

Each of the first and second hole transport units HTU1 and HTU2 may include at least one of a hole injection layer or a hole transport layer and may further include a hole buffer layer and/or an electron blocking layer, as necessary. The first and second hole transport units HTU1 and HTU2 may have the same configuration or different configurations.

Each of the first and second electron transport units ETU1 and ETU2 may include at least one of an electron injection layer or an electron transport layer and may further include an electron buffer layer and/or a hole blocking layer, as necessary. The first and second electron transport units ETU1 and ETU2 may have the same configuration or different configurations.

An intermediate layer (or a connection layer), which may be provided in the form of a charge generation layer CGL, may be arranged between the first emission unit EU1 and the second emission unit EU2 to connect the first emission unit EU1 and the second emission unit EU2 to each other. Hereinafter, the charge generation layer CGL will be referred to as an intermediate layer. In one or more embodiments, the intermediate layer CGL may have a stacked structure of a p dopant layer and an n dopant layer. For example, the p dopant layer may include a p-type (kind) dopant such as 1,4,5,8,9,11-hexaazatriphenylenehexacarbonitrile (HAT-CN), 7,7,8,8-tetracyanoquinodimethane (TCNQ), or 2-(7-dicyanomethylene-1,3,4,5,6,8,9,10-octafluoro-7H-pyrene-2-ylidene)-malononitrile (NDP-9), and the n dopant layer may include an alkali metal, an alkaline earth metal, a lanthanide metal, and/or a (e.g., any suitable) combination thereof. However, the structure (or material) of the intermediate layer CGL is not limited to the above-described embodiments. In one or more embodiments, the intermediate layer CGL may have conductivity by including a material with relatively high charge conductivity (or charge mobility) as compared to the first and second emission units EU1 and EU2.

In one or more embodiments, the first emission layer EML1 and the second emission layer EML2 may generate pieces of light with different colors. Pieces of light emitted from the first and second emission layers EML1 and EML may be mixed and viewed as white light (e.g., combined white light). For example, in one or more embodiments, the first emission layer EML1 may generate blue color light, and the second emission layer EML2 may include a structure in which a first sub-emission layer configured to generate red color light and a second sub-emission layer configured to generate green color light are stacked. In these embodiments, a functional layer configured to perform a function of transporting holes and/or blocking transport of electrons may be further arranged between the first sub-emission layer and the second sub-emission layer.

In one or more embodiments, the first emission layer EML1 and the second emission layer EML2 may generate light with the same color.

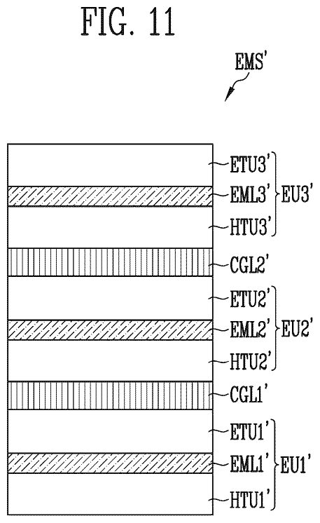

FIG. 11 is a schematic cross-sectional view illustrating an emission structure EMS' included in one of the first to third light-emitting elements of FIG. 8 or FIG. 9 according to one or more embodiments of the present disclosure.

Referring to FIG. 11, the emission structure EMS' may have a tandem structure in which first, second, and third emission units EU1′, EU2′, and EU3′ are stacked. The emission structure EMS' may be provided to be substantially the same in the first to third light-emitting elements LD1 to LD3 of FIG. 8. In addition, the emission structure EMS' may be provided to be substantially the same in the first to third light-emitting elements LD1′ to LD3′ of FIG. 9.

Each of the first to third emission units EU1′ to EU3′ may include an emission layer that generates light according to an applied current. The first emission unit EU1 may include a first emission layer EML1′, a first electron transport unit ETU1′, and a first hole transport unit HTU1′. The first emission layer EML1′ may be arranged between the first electron transport unit ETU1′ and the first hole transport unit HTU1′. The second emission unit EU2′ may include a second emission layer EML2′, a second electron transport unit ETU2′, and a second hole transport unit HTU2′. The second emission layer EML2′ may be arranged between the second electron transport unit ETU2′ and the second hole transport unit HTU2′. The third emission unit EU3′ may include a third emission layer EML3′, a third electron transport unit ETU3′, and a third hole transport unit HTU3′. The third emission layer EML3′ may be arranged between the third electron transport unit ETU3′ and the third hole transport unit HTU3′.

Each of the first to third hole transport units HTU1′ to HTU3′ may include at least one of a hole injection layer or a hole transport layer and may further include a hole buffer layer and/or an electron blocking layer, as necessary. The first to third hole transport units HTU1′ to HTU3′ may have the same configuration or different configurations.

Each of the first to third electron transport units ETU1′ to ETU3′ may include at least one of an electron injection layer or an electron transport layer and may further include an electron buffer layer and/or a hole blocking layer, as necessary. The first to third electron transport units ETU1′ to ETU3′ may have the same configuration or different configurations.

A first intermediate layer CGL1′ may be arranged between the first emission unit EU1′ and the second emission unit EU2′. A second intermediate layer CGL2′ may be arranged between the second emission unit EU2′ and the third emission unit EU3′. In one or more embodiments, the first intermediate layer CGL1′ and the second intermediate layer CGL2′ may each have conductivity by including a material with relatively high charge conductivity (or charge mobility) as compared to the first emission unit EU1′, the second emission unit EU2′, and the third emission unit EU3′.

In one or more embodiments, the first to third emission layers EML1′ to EML3′ may generate pieces of light with different colors. Pieces of light emitted from the first to third emission layers EML1′ to EML3′ may be mixed and viewed as white light (e.g., combined white light). For example, in one or more embodiments, the first emission layer EML1′ may generate blue color light, the second emission layer EML2′ may generate green color light, and the third emission layer EML3′ may generate red color light.

In one or more embodiments, two or more emission layers selected from among the first to third emission layers EML1′ to EML3′ may generate light with the same color.

Hereinafter, a method of manufacturing a display device DD (see FIG. 5) according to one or more embodiments of the present disclosure will be described.

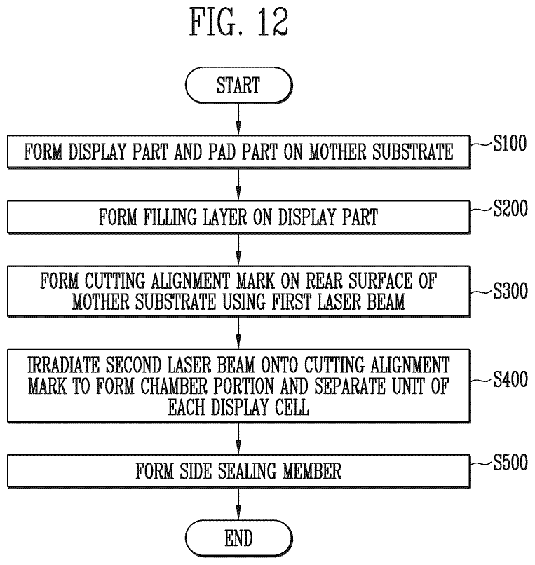

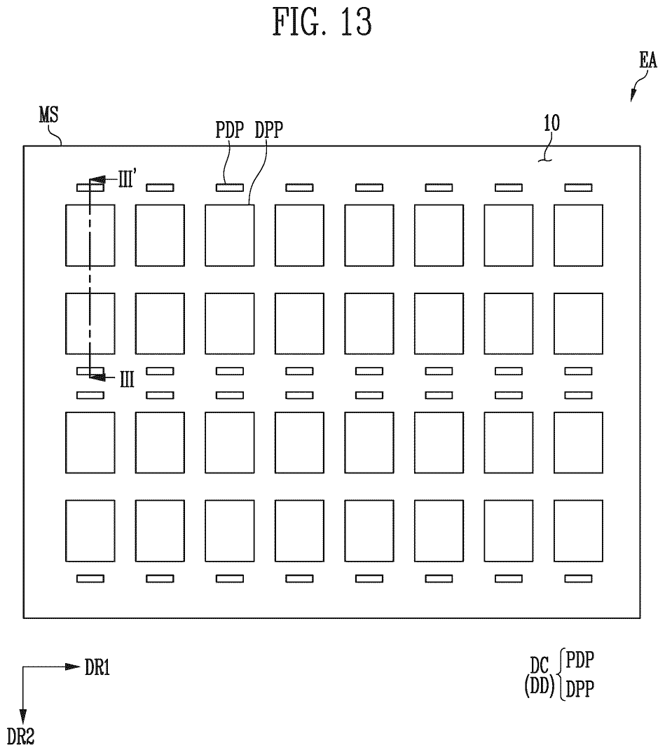

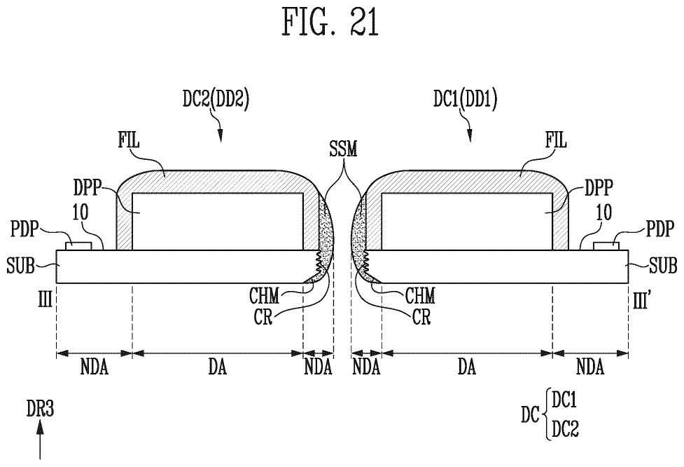

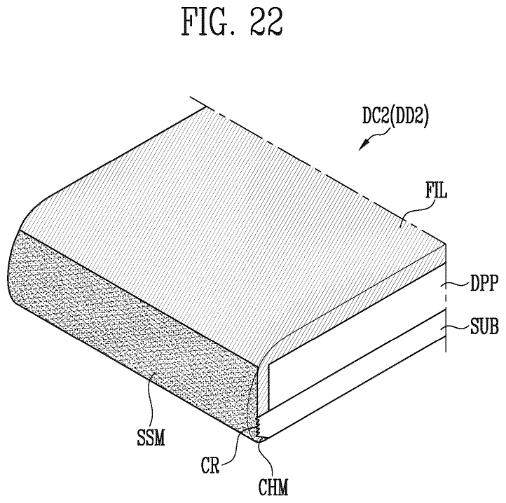

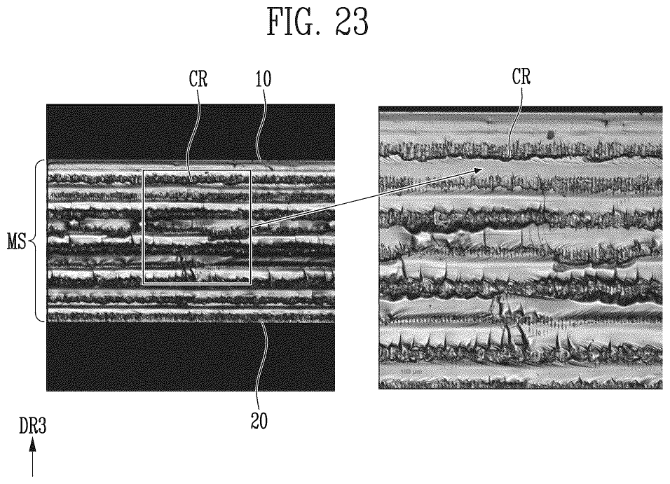

FIG. 12 is a schematic block diagram illustrating a method of manufacturing a display device according to one or more embodiments of the present disclosure. FIGS. 13 to 21 are plan views and cross-sectional views illustrating process operations of the method of manufacturing a display device according to one or more embodiments of the present disclosure. FIG. 22 is a schematic cross-sectional perspective view illustrating a portion of a second display cell of FIG. 21. FIG. 23 shows schematic images showing cracks in FIG. 19.

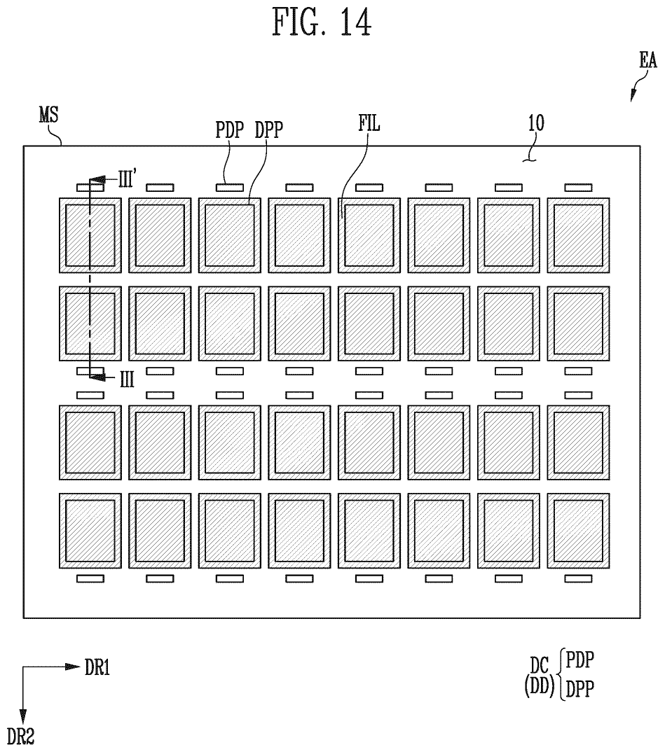

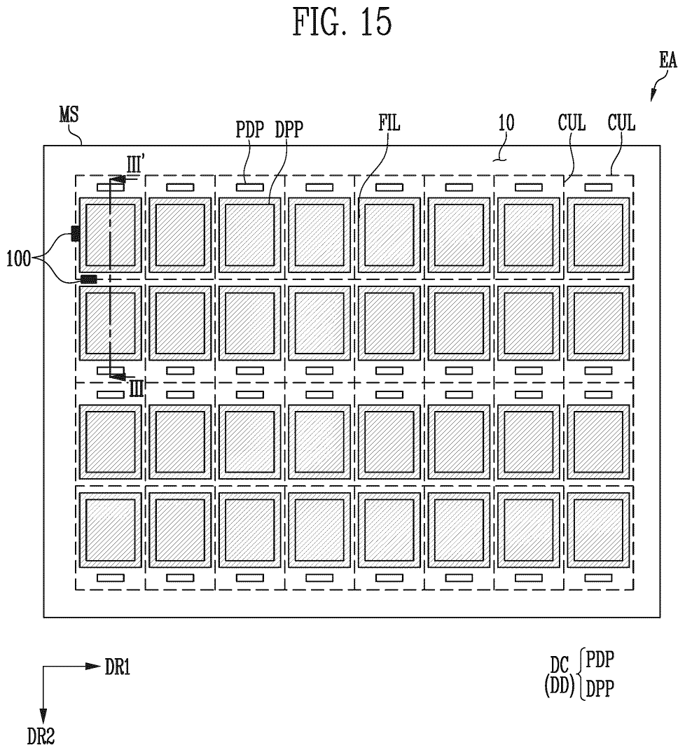

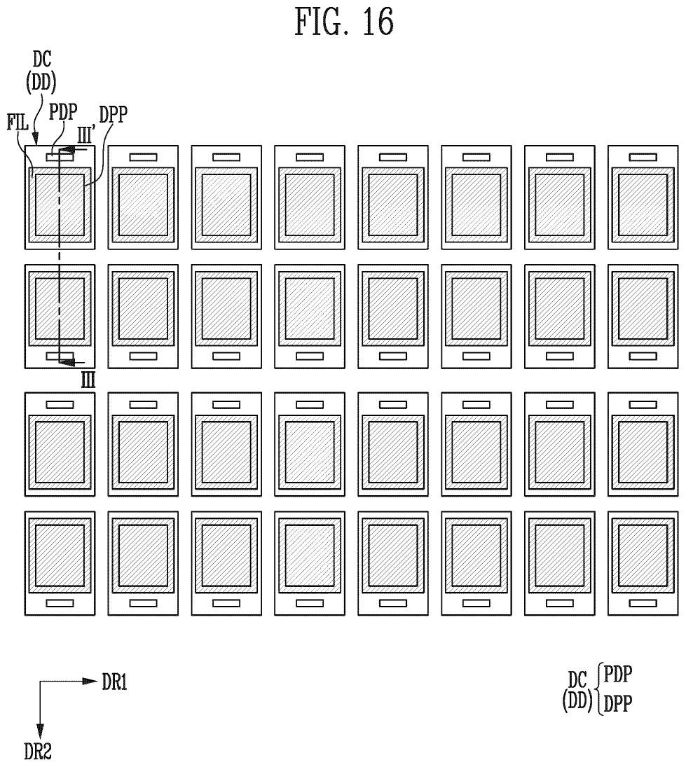

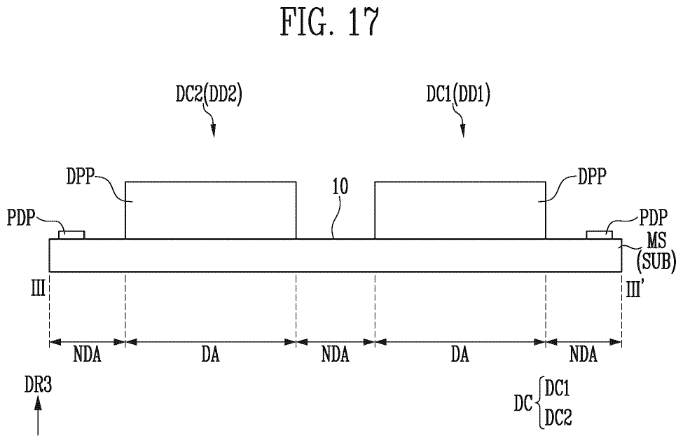

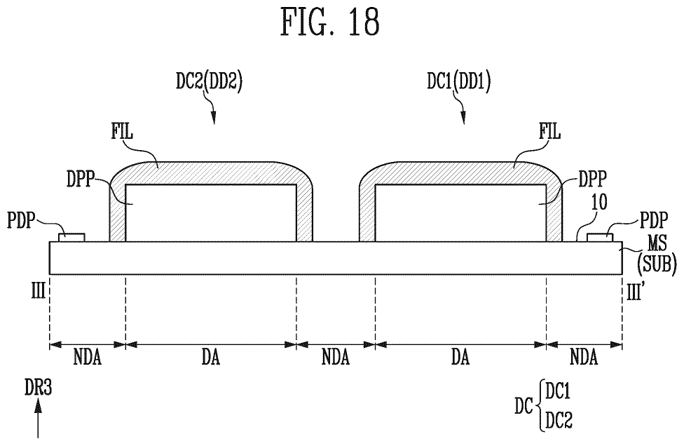

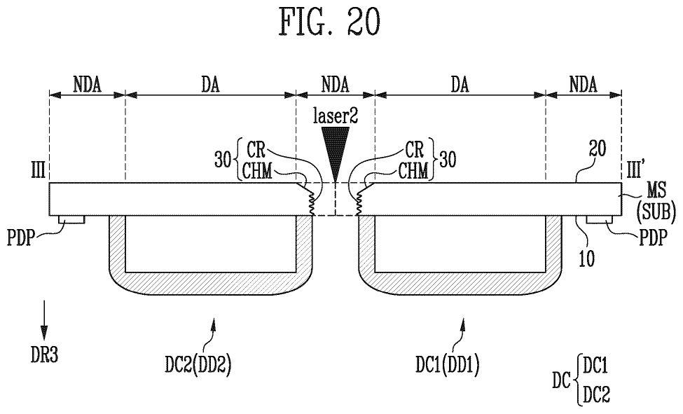

For example, FIG. 13 is a view for describing first operation S100 of FIG. 12 and is a schematic plan view of a mother substrate MS corresponding to portion EA of FIG. 1, FIG. 14 is a view for describing second operation S200 of FIG. 12 and is a schematic plan view of the mother substrate MS corresponding to portion EA of FIG. 1, FIG. 15 is a view for describing third second operation S300 of FIG. 12 and is a schematic plan view of the mother substrate MS corresponding to portion EA of FIG. 1, FIG. 16 is a view for describing fourth operation S400 of FIG. 12 and is a schematic plan view of the mother substrate MS corresponding to portion EA of FIG. 1, FIG. 17 is a schematic cross-sectional view taken along the line III-III′ of FIG. 13, FIG. 18 is a schematic cross-sectional view taken along the line III-III of FIG. 14, FIG. 19 is a schematic cross-sectional view taken along the line III-III′ of FIG. 15, FIG. 20 is a schematic cross-sectional view taken along the line III-III′ of FIG. 16, and FIG. 21 is a view for describing fifth operation S500 of FIG. 12 and is a schematic cross-sectional view corresponding to line III-III′ of FIG. 16.

Although operations of manufacturing the display device DD are described as being performed sequentially in one or more embodiments of FIGS. 12 to 23, unless the spirit of present disclosure is changed, it is obvious that some operations shown as being performed sequentially may be performed concurrently (e.g., simultaneously), the order of each operation may be changed, some operations may be omitted (e.g., not be performed), or other operations may be further included between respective operations.

In FIGS. 12 to 23, for convenience of description, descriptions that overlap those of the above-described embodiments will not be provided for conciseness.

Referring to FIGS. 12, 13, and 17, a plurality of display cells DC (or display devices DD) are formed on a first surface 10 of the mother substrate MS. (S100—first operation)

The mother substrate MS may be a substrate for concurrently (e.g., simultaneously) manufacturing the plurality of display cells DC for process convenience and may be a substrate SUB of the display device DD. In other words, the mother substrate MS may be the substrate on which a plurality of display cells DC (or display devices DD) are manufactured for process convenience. The mother substrate MS may include one or more unit areas. The unit area may be a portion corresponding to an individual display cell DC (or an individual display device DD), and the individual display cell DC may be formed in each unit area.

In one or more embodiments, each of the display cells DC may be individually separated to serve as the display device DD, and the plurality of display cells DC may be formed concurrently (e.g., simultaneously) on the mother substrate MS and then separated through a cutting process and/or the like. The plurality of display cells DC may be provided on the first surface 10 (or an upper surface) of the mother substrate MS and may be arranged in a matrix form according to a row (or display cell row) extending in a first direction DR1 and a column (or a display cell column) extending a second direction DR2.

Each of the display cells DC may include a display part DPP and a pad part PDP.

The display cells DC may include first display cells DC1 arranged in odd-numbered rows and second display cells DC2 arranged in even-numbered rows on the mother substrate MS. Each of the first and second display cells DC1 and DC2 may include the display part DPP arranged in a display area DA and the pad part PDP arranged in a non-display area NDA.

The display part DPP may be the display part described with reference to FIGS. 7 to 11.

Referring to FIGS. 12, 14, and 18, a filling layer FIL is formed on the display part DPP of each display cell DC. (S200—second operation)

A coating solution including a transparent curable resin having a viscosity of a certain viscosity or more, for example, about 2,000, is applied on the display part DPP of each of the display cells DC using a jet dispenser and/or the like, and then the filling layer FIL is formed by performing a curing process in which heat curing, UV curing, or both (e.g., simultaneously) heat curing and UV curing are performed.

In embodiments in which the coating solution has a viscosity of a certain level or more, the spreadability of the coating solution toward the pad part PDP may be limited or prevented such that the coating solution is spaced and/or apart (e.g., spaced apart or separated) from the pad part PDP adjacent to the display part DPP if (e.g., when) the coating solution is applied on the display part DPP.

The filling layer FIL cured through the above-described curing process may have a hardness of a certain level or more, and due to the viscosity of the coating solution which is a base material of the filling layer FIL, the filling layer FIL may have a corner that is curved or rounded toward an edge of the display part DPP. The filling layer FIL having the curved or rounded corner may further improve the mechanical strength of each display cell DC by dispersing external impacts in one or more suitable directions. The filling layer FIL may be positioned on an uppermost layer of each display cell DC in a third direction DR3 and may provide a display surface and/or an input surface to a user. The filling layer FIL may be a protective layer or a cover member that protects each display cell DC from an external impact and/or the like.

Referring to FIGS. 12, 15, and 19, after a laser device having a wavelength that penetrates the mother substrate MS is positioned on the first surface 10 of the mother substrate MS, a first laser beam (laser1) is irradiated onto a boundary point between two adjacent display cells DC to form a cutting alignment mark CUL on a second surface 20 (rear surface or lower surface opposite to the first surface 10) of the mother substrate MS. (S300—third operation)

For example, in one or more embodiments, the first laser beam that penetrates the mother substrate MS may be an infrared laser with a wavelength of 1,000 nm or more, but embodiments of the present disclosure are not limited thereto.

The first laser beam may be irradiated on the first surface 10 of the mother substrate MS corresponding to a point bisecting a boundary area BA between two adjacent display cells DC, for example, a first display cell DC1 and a second display cell DC2 that are arranged adjacent to each other in the second direction DR2, thereby forming the cutting alignment mark CUL on the second surface 20 of the mother substrate MS corresponding to the above point. In one or more embodiments, a gap between two adjacent display cells may be in a range of about 5 micrometers (μm) to about 50 μm, but embodiments of the present disclosure are not limited thereto.

In embodiments in which the first laser beam is irradiated onto a preset area (for example, the point bisecting the boundary area BA between adjacent display cells), the cutting alignment mark CUL may be formed on the second surface 20 of the mother substrate MS by using a focus adjustment method of focusing the laser device irradiating the first laser beam on the rear surface of the mother substrate MS or by using an irradiation method such as a dual laser device and/or the like.

In the embodiments in which the first laser beam is irradiated onto the preset area of the mother substrate MS, a crack CR corresponding to a laser processing mark may be formed inside the mother substrate MS. The crack CR may be formed inside the mother substrate MS in the preset area onto which the first laser beam is irradiated and may be implemented as the cutting alignment mark CUL in the form of a line on the second surface 20 of the mother substrate MS. As shown in FIG. 23, a plurality of cracks CR in the form of lines extending in a direction intersecting a thickness direction of the mother substrate MS may be formed on a cross section of the mother substrate MS onto which the first laser beam is irradiated. For example, in embodiments in which the mother substrate MS has a thickness of 700 μm or more, 3 to 15 cracks in the form of a line may be formed on the cross section of the mother substrate MS onto which the first laser beam is irradiated.

Referring to FIGS. 12, 16, and 20, after the mother substrate MS is turned over such that the second surface 20 of the mother substrate MS faces upward, a second laser beam (laser2) is irradiated onto the cutting alignment mark CUL to separate the mother substrate MS (see FIG. 15) into units of the display cells DC. (S400—fourth operation)

In one or more embodiments, the second laser beam may be an ultra-short pulse laser with a short wavelength (for example, UV and green) that is adsorbed by the mother substrate MS, but embodiments of the present disclosure are not limited thereto.

In embodiments in which the second laser beam is intensively irradiated onto the cutting alignment mark CUL formed on the second surface 20 of the mother substrate MS, a portion of the second surface 20 of the mother substrate MS may be removed to form a groove that is recessed in a direction toward the first surface 10. As the mother substrate MS expands due to heat generated when the second laser beam is irradiated, the crack CR formed inside the mother substrate MS in the above-described third operation propagates to cause the mother substrate MS to be naturally fractured, thereby forming each display cell DC. In these embodiments, a side surface 30 of the substrate SUB of each display cell DC may serve as a cut surface. The side surface 30 of the substrate SUB may be positioned between the first surface 10 of the mother substrate MS (or the substrate SUB) on which the display part DPP is formed and the second surface 20 opposite to the first surface 20 and may be connected to each of the first surface 10 and the second surface 20.

While the mother substrate MS is fractured, the groove may be transformed into chamfer portions CHM formed in two adjacent display cells DC, for example, on the side surface 30 of the substrate SUB of the first display cell DC1 and the side surface 30 of the substrate SUB of the second display cell DC2. For example, the chamfer portion CHM may be formed on at least a portion of the side surface 30 of the substrate SUB of each of the first and second display cells DC1 and DC2. At least a portion of the side surface 30 of the substrate SUB of each display cell DC may have a certain gradient due to the chamfer portion CHM.

In one or more embodiments, in each display cell DC individually separated due to the mother substrate MS is fractured, at least a portion of the side surface 30 of the substrate SUB may be positioned on the same line as an edge of the filling layer FIL in a thickness direction of the substrate SUB, but embodiments of the present disclosure are not limited thereto.

In one or more embodiments, the chamfer portion CHM may be formed on the entire side surface 30 of the substrate SUB of each display cell DC. The chamfer portion CHM in each display cell DC may additionally increase a level of edge reliability of the substrate SUB (or an ability to withstand stress and edge impact), thereby further improving the mechanical stability of each display cell DC.

In the third operation, the crack CR formed inside the mother substrate MS may propagate in a direction parallel to the first surface 10 (and/or the second surface 20) of the mother substrate MS in an operation of irradiating the second laser beam, thereby remaining on a cut surface of each display cell DC when the mother substrate MS is fractured. Thus, at least a portion of the cut surface of each display cell DC (or the side surface 30 of the substrate SUB) may have a curved surface due to the crack CR.

In the above-described embodiments, the chamfer portion CHM having a certain gradient may be formed on at least a portion of the side surface 30 of the substrate SUB of each display cell DC, and the crack CR forming a curved surface may be formed on the remainder of the side surface 30.

Referring to FIGS. 12, 21, and 22, a side sealing member SSM is formed to cover the cut surface of each display cell DC. (S500—fifth operation)

Before the side sealing member SSM is formed, for process convenience, each display cell DC may be turned upside down such that the filling layer FIL of each display cell DC faces upward.

The side sealing member SSM may include a curable resin having a viscosity of a certain level or more. The side sealing member SSM may be arranged on the chamfer portion CHM, the cut surface of each display cell DC (or the side surface 30 of the substrate SUB), and a side surface of the filling layer FIL to cover the chamfer portion CHM, the cut surface of each display cell DC, and the side surface of the filling layer FIL. The side sealing member SSM may include a moisture-proof and water-repellent material that prevents the penetration of moisture.

After such a process, a cleaning process may be further performed to remove foreign materials on a surface of the substrate SUB.

The separated display cells DC may be used in one or more suitable electronic devices such as televisions (TVs), smartphones, wearable devices, and/or the like. For example, in one or more embodiments, the separated display cells DC may be used in devices for implementing VR or AR.

According to the above-described embodiments, the first laser beam that penetrates the mother substrate MS (or the substrate SUB) may be irradiated onto a preset area of the first surface 10 of the mother substrate MS to form the cutting alignment mark CUL on the second surface 20 of the mother substrate MS, and the second laser beam that is absorbed by the mother substrate MS may be directly irradiated onto the cutting alignment mark CUL to separate the mother substrate MS into a unit of each display cell DC, thereby forming the chamfer portion CHM at the edge of each display cell DC.

As described above, in a process of separating the mother substrate MS into a unit of each display cell DC, the chamfer portion CHM that improves the mechanical strength of each display cell DC may be formed concurrently (e.g., simultaneously). Accordingly, a process of separately forming the chamfer portion CHM may not be provided or needed, thereby improving the manufacturing efficiency of the display device DD.

In addition, the side sealing member SSM may be formed on the side surface 30 of the substrate SUB of each display cell DC to cover the side surface 30 of the substrate SUB so that the chamfer portion CHM and the crack CR positioned on the cut surface of the above substrate SUB may not be exposed to the outside. In this regard, a polishing process of gently making the cut surface (or the side surface) of the substrate SUB which is curved or sharp due to a cutting process and/or the like may not be provided or required, thereby further improving the manufacturing efficiency of the display device DD.

In the above-described embodiments, it has been described that, through a process of irradiating the first laser beam that penetrates the mother substrate MS and a process of irradiating the second laser beam that is absorbed by the mother substrate MS, in a process of separating the mother substrate MS into a unit of each display cell, the chamfer portion CHM is formed in each display cell DC, but embodiments of the present disclosure are not limited thereto. According to one or more embodiments, the mother substrate MS may be separated into a unit of each display cell DC only through a process of irradiating a laser beam that penetrates the mother substrate MS, and the chamfer portion CHM may also be formed in each of the separated display cells DC.

For example, the process involves using a first laser beam to penetrate the mother substrate MS and form a cutting alignment mark CUL on the second surface of the substrate. A second laser beam, absorbed by the substrate, is then used to directly irradiate the cutting alignment mark, separating the mother substrate into individual display cells DC and concurrently forming a chamfer portion CHM at the edge of each display cell. This concurrent or simultaneous formation of the chamfer portion CHM enhances the mechanical strength of each display cell and eliminates the need for a separate chamfering process, thereby improving manufacturing efficiency.

Additionally, a side sealing member SSM is applied to cover the side surface of each display cell, ensuring that the chamfer portion CHM and any cracks on the cut surface are not exposed. This approach negates the need for a polishing process to smoothen the cut surfaces, further enhancing the manufacturing efficiency of the display device. The described method emphasizes the efficiency and reliability improvements in the production of display devices by integrating the chamfering process with the laser cutting operations.

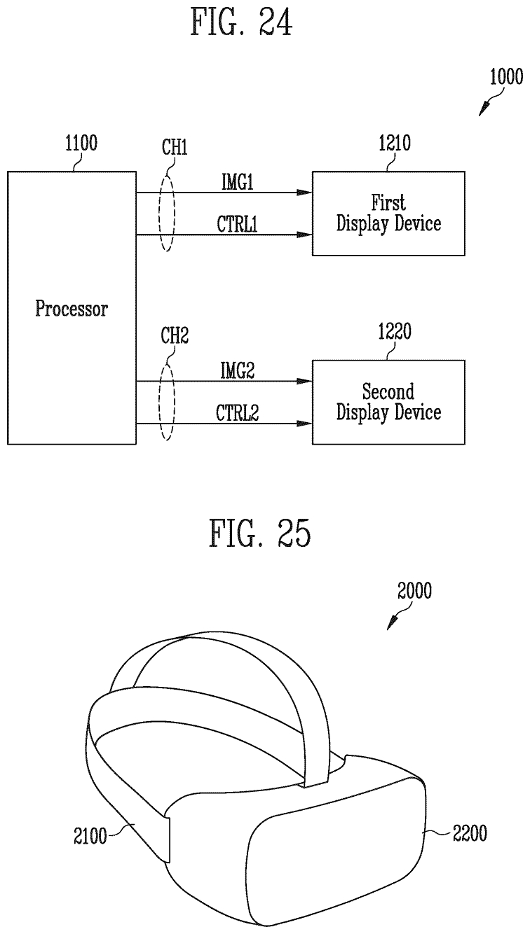

FIG. 24 is a schematic block diagram illustrating a display system according to one or more embodiments of the present disclosure.

Referring to FIG. 24, a display system 1000 may include a processor 1100 and one or more display devices 1210 and 1220.

The processor 1100 may perform one or more suitable tasks and calculations. In one or more embodiments, the processor 1100 may include an application processor, a graphics processor, a microprocessor, a central processing unit (CPU), and/or the like. The processor 1100 may be connected to other components of the display system 1000 through a bus system to control the other components.

In FIG. 24, the display system 1000 is shown as including first and second display devices 1210 and 1220. The processor 1100 may be connected to the first display device 1210 through a first channel CH1 and may be connected to the second display device 1220 through a second channel CH2.

Through the first channel CH1, the processor 1100 may be to transmit first image data IMG1 and a first control signal CTRL1 to the first display device 1210. The first display device 1210 may display an image based on the first image data IMG1 and the first control signal CTRL1. The first display device 1210 may have the same configuration as the display device DD described with reference to FIG. 4.

Through the second channel CH2, the processor 1100 may be to transmit second image data IMG2 and a second control signal CTRL2 to the second display device 1220. The second display device 1220 may display an image based on the second image data IMG2 and the second control signal CTRL2. The second display device 1220 may have the same configuration as the display device DD described with reference to FIG. 4.

The display system 1000 may include a computing system for providing an image display function, such as a portable computer, a mobile phone, a smartphone, a tablet personal computer (PC), a smart watch, a watch phone, a portable multimedia player (PMP), a navigation device, or an ultra-mobile personal computer (UMPC). In addition, the display system 1000 may include at least one of an HMD device, a VR device, an MR device, or an AR device.

FIG. 25 is a schematic perspective view illustrating an application example of the display system of FIG. 24 according to one or more embodiments of the present disclosure.

Referring to FIG. 25, in one or more embodiments, the display system 1000 of FIG. 24 may be applied to an HMD device 2000. The HMD device 2000 may be a wearable electronic device that can be worn on a head of a user.

The HMD device 2000 may include a head-mounted band 2100 and a display device accommodation case 2200. The head-mounted band 2100 may be connected to the display device accommodation case 2200. The head-mounted band 2100 may include a horizontal band and/or a vertical band which are for fixing the HMD device 2000 to a head of a user. The horizontal band may be configured to be around (e.g., surround) a side portion of a head of a user, and the vertical band may be configured to be around (e.g., surround) an upper portion of the head of the user. However, embodiments of the present disclosure are not limited thereto. For example, in one or more embodiments, the head-mounted band 2100 may be implemented in the form of a glasses frame, a helmet, and/or the like.

The display device accommodation case 2200 may accommodate the first and second display devices 1210 and 1220 of FIG. 24. The display device accommodation case 2200 may further accommodate the processor 1100 of FIG. 24.

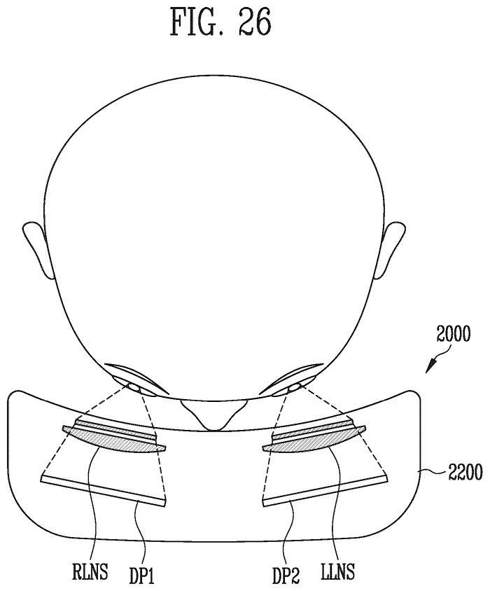

FIG. 26 is a schematic view illustrating a state in which a user wears the HMD device of FIG. 25 according to one or more embodiments of the present disclosure.

Referring to FIG. 26, in the HMD device 2000, a first display panel DP1 of a first display device 1210 (see FIG. 24) and a second display panel DP2 of a second display device 1220 (see FIG. 24) are arranged. The HMD device 2000 may further include one or more lenses LLNS and RLNS.

In the display device accommodation case 2200, a right eye lens RLNS may be arranged between the first display panel DP1 and a right eye of a user. In the display device accommodation case 2200, a left eye lens LLNS may be arranged between the second display panel DP2 and a left eye of the user.

In one or more embodiments, an image output from the first display panel DP1 may be displayed to the right eye of the user through the right eye lens RLNS. The right eye lens RLNS may refract light from the first display panel DP1 to be directed toward the right eye of the user. The right eye lens RLNS may perform an optical function of adjusting a viewing distance between the first display panel DP1 and the right eye of the user.

In one or more embodiments, an image output from the second display panel DP2 may be displayed to the left eye of the user through the left eye lens LLNS. The left eye lens LLNS may refract light from the second display panel DP2 to be directed toward the left eye of the user. The left eye lens LLNS may perform an optical function of adjusting a viewing distance between the second display panel DP2 and the left eye of the user.

In one or more embodiments, the right eye lens RLNS and the left eye lens LLNS may each include an optical lens having a pancake-shaped cross section. In one or more embodiments, the right eye lens RLNS and the left eye lens LLNS may each include a multi-channel lens including sub-areas with different optical properties. In these embodiments, each display panel may output images corresponding to the sub-areas of the multi-channel lens, and the output images may respectively pass through the sub-areas and be viewed by a user.

According to one or more embodiments, in a mother substrate including a plurality of display cells, a first laser beam that penetrates the mother substrate may be irradiated between the display cells to form a cutting alignment mark on a rear surface of the mother substrate, and a second laser beam that is absorbed by the mother substrate may be irradiated onto the cutting alignment mark to form a chamfer portion in each of the display cells, thereby individually separating each of the display cells.

Accordingly, the chamfer portion may be formed on a side surface of each display cell in a process of individually separating the display cells, and thus a separate process of forming the chamfer portion may not be provided, thereby providing a display device with improved manufacturing efficiency.

The effects and aspects according to one or more embodiments are not limited to the contents discussed above, and more one or more suitable effects and aspects are included in the present disclosure.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The display device-manufacturing apparatus, the display device, the electronic devices/apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although specific example embodiments and applications have been described herein, one or more embodiments and modifications may be derived from the above description. Accordingly, the technical scope of the present disclosure is not limited to such embodiments, but rather to the broader scope of the presented claims and one or more suitable obvious modifications and equivalent arrangements.

What is claimed is:

1. A display device, comprising:
a substrate in which a display area and a non-display area are defined and which has a first surface and a second surface opposite to each other in a thickness direction thereof and a side surface positioned between the first surface and the second surface;
a display part on the first surface of the substrate in the display area and configured to display an image;
a pad part on the first surface of the substrate in the non-display area;
a filling layer on the display part and configured to cover the display part; and
a chamfer portion positioned on at least a portion of the side surface of the substrate,
wherein the side surface of the substrate comprises at least one crack extending in a direction intersecting the thickness direction.

2. The display device of claim 1, wherein the side surface of the substrate connected to the chamfer portion has a curved surface.

3. The display device of claim 1, wherein the filling layer comprises a transparent curable resin and is positioned on an uppermost layer of the display part in the display area.

4. The display device of claim 1, wherein the substrate comprises a silicon wafer substrate.

5. The display device of claim 1, further comprising a side sealing member on the chamfer portion to cover the chamfer portion.

6. The display device of claim 1, wherein the display part comprises:
an anode on the substrate;
a pixel defining layer on the substrate and comprising an opening configured to expose a portion of the anode;
an emission structure on the anode and the pixel defining layer; and
a cathode on the emission structure.

7. The display device of claim 6, wherein the emission structure comprises:
a first emission unit on the anode and the pixel defining layer and configured to emit light;
an intermediate layer on the first emission unit; and
a second emission unit on the intermediate layer and configured to emit light.

8. The display device of claim 6, wherein the emission structure comprises:
a first emission unit on the anode and the pixel defining layer and configured to emit light;
a first intermediate layer on the first emission unit;
a second emission unit on the first intermediate layer and configured to emit light;
a second intermediate layer on the second emission unit; and
a third emission unit on the second intermediate layer and configured to emit light.

9. A wearable electronic device, comprising:
a display panel; and
a lens on the display panel,
wherein the display panel comprises:
a substrate in which a display area and a non-display area are defined and which has a first surface and a second surface opposite to each other in a thickness direction thereof and a side surface positioned between the first surface and the second surface;
a display part on the first surface of the substrate in the display area and configured to display an image;
a pad part on the first surface of the substrate in the non-display area;
a filling layer on the display part and configured to cover the display part; and
a chamfer portion positioned on at least a portion of the side surface of the substrate,
wherein the side surface of the substrate comprises at least one crack extending in a direction intersecting the thickness direction.

10. The wearable electronic device of claim 9, wherein the filling layer comprises a transparent curable resin and is positioned on an uppermost layer of the display part in the display area.

11. The wearable electronic device of claim 9, wherein the substrate comprises a silicon wafer substrate.

12. The wearable electronic device of claim 9, wherein the display panel further comprises a side sealing member on the chamfer portion to cover the chamfer portion.

13. The wearable electronic device of claim 9, wherein the display part comprises:
an anode on the substrate;
a pixel defining layer on the substrate and comprising an opening configured to expose a portion of the anode;
an emission structure on the anode and the pixel defining layer; and
a cathode on the emission structure.

14. A method, comprising:
providing a mother substrate comprising a plurality of display cells;
forming a filling layer on a display part of each of the display cells;
irradiating a first laser beam onto a first surface of the mother substrate corresponding to a boundary point between two adjacent display cells among the display cells, and forming a cutting alignment mark on a second surface of the mother substrate opposite to the first surface; and
turning over the mother substrate so that the second surface faces upward, irradiating a second laser beam onto the cutting alignment mark to form a chamfer portion, and then individually separating each of the display cells,
wherein the method is a method of manufacturing a display device.

15. The method of claim 14, wherein the first laser beam is a laser having a wavelength that penetrates the mother substrate, and
the second laser beam is a laser having a wavelength that is absorbed by the mother substrate.

16. The method of claim 14, wherein the mother substrate comprises a silicon wafer substrate,
the first laser beam comprises an infrared laser, and
the second laser beam comprises a visible light laser.

17. The method of claim 14, wherein, in the forming of the cutting alignment mark, when the first laser beam is irradiated onto the first surface of the mother substrate, at least one crack is formed inside the mother substrate.

18. The method of claim 17, wherein, in the individually separating of each of the display cells, when the second laser beam is irradiated onto the cutting alignment mark, heat is generated, and the crack propagates due to the heat so that the mother substrate expands to be separated into each of the display cells individually.

19. The method of claim 14, further comprising, after the individually separating of each of the display cells, forming a side sealing member configured to cover the chamfer portion.

20. The method of claim 14, wherein the filling layer comprises a transparent curable resin and is positioned on an uppermost layer of the display part of each of the display cells.
